(19) United States
(12) Patent Application Publication
(10) Pub. No.: US 2024/0202408 A1
(43) Pub. Date: Jun. 20, 2024

(54) SYSTEM DESIGN LEARNING APPARATUS, SYSTEM DESIGNLEARNING METHOD, AND COMPUTER-READABLE RECORDING MEDIUM

(71) Applicant: NEC Corporation, Tokyo (JP)

(72) Inventor: Yutaka YAKUWA, Tokyo (JP)

(73) Assignee: NEC Corporation, Tokyo (JP)

(21) Appl. No.: 18/539,547

(22) Filed: Dec. 14, 2023

(30) Foreign Application Priority Data
Dec. 19, 2022 (JP) 2022-202506
May 25, 2023 (JP) 2023-086410

(51) Int. Cl. G06F 30/27

(52) U.S. Cl. CPC G06F 30/27

(57) ABSTRACT

A system design learning apparatus including: a design unit that, with respect to a system requirement that is information representing a configuration of a system including an abstract part, executes concretization processing in which the abstract part is converted to a concrete part, generates a concrete system configuration, and generates configuration path information representing a process of generating the concrete system configuration from the system requirement; a reward setting unit that sets rewards to the system requirement, a system configuration idea, and the concrete system configuration, respectively; a conversion unit that generates abstract configuration path information by abstractizing the configuration path information; a learning data generation unit that generates learning data by associating the rewards with an abstractized system requirement, an abstractized system configuration idea, and an abstractized concrete system configuration, respectively; and a learning unit that learns a design method of the system based on the learning data.

### CROSS-REFERENCE TO RELATED APPLICATION

This application is based upon and claims the benefit of priority from Japanese patent applications No. 2023-086410, filed on May 25, 2023, and No. 2022-202506, filed on Dec. 12, 2022, the disclosure of which is incorporated herein in its entirety by reference.

### BACKGROUND OF THE INVENTION

### 1. Field of the Invention

The present disclosure relates to a system design learning apparatus, a system design learning method, and a computer-readable recording medium that are used in system design.

### 2. Background Art

When designing an ICT (Information and Communication Technology) system, first, in requirement definition, a designer creates information (system requirement) representing an ICT system configuration including concrete elements and abstract elements in which client requirements and requests are consolidated.

The ICT system configuration can be represented by a graph based on concepts such as IBN (Intent-Based Networking). In the graph, the elements (components) included in the ICT system configuration are represented by nodes and edges. A node is a component representing a device or an application, for example. An edge is a component representing a connection relationship between two nodes, or the like.

Next, in automated design, abstract parts included in the system requirements are concretized based on a concretization rule created in advance, and information (concrete system configuration) representing an ICT system configuration in a deployable state is derived.

The concretization rule is information that is used to convert an abstract part into a concrete part by concretizing, step by step, the abstract part.

A concrete part represents a component or configuration that is determined as being actually used in the ICT system. The abstract part represents an undetermined component or configuration for which, although the function is determined, a component or configuration that is actually used in the system is not concretely determined.

As a related technique, in Patent Document 1 (International Publication No. WO/2019/216082), a system configuration derivation apparatus is disclosed that, by concretizing abstract elements step by step, derives a concrete system configuration of a deployable ICT system. According to the system configuration derivation apparatus of Patent Document 1, undetermined elements included in the system requirements are concretized step by step using a concretization rule to ultimately derive an implementable concrete system configuration.

Specifically, the system configuration derivation apparatus of Patent Document 1 detects at least one abstract part included in the system requirements, converts the detected abstract part into a concrete part using a concretization rule, and generates a system configuration idea or a concrete system configuration.

The system configuration idea is information representing a configuration including an abstract part, prior to derivation of a concrete system configuration. Therefore, a system requirement can also be considered to be a system configuration idea.

When the system configuration idea includes an abstract part, the abstract part is again converted using the concretization rule. Thereafter, conversion is repeated, and when all parts are concretized, it is considered that the concrete system configuration is derived.

Incidentally, when the system requirement and system configuration idea are concretized, a plurality of concretization rules are applied. As a result, the system configuration idea or concrete system configuration to be derived changes according to the selected concretization rule or the order in which concretization rules are selected. Therefore, system configuration ideas and concrete system configurations having different configurations are derived depending on the order in which concretization rules are selected.

Also, when the number of concretization rules to be applied increases, the number of system configuration ideas and concrete system configurations that are to be generated increases dramatically. Moreover, the plurality of different concrete system configurations may include a concrete system configuration that does not satisfy the system requirement. Therefore, with the system configuration derivation apparatus of Patent Document 1, it is envisioned that the concrete system configuration cannot be efficiently derived.

Therefore, in order to efficiently derive a concrete system configuration, it is important to appropriately select the concretization rules and appropriately determine the suitability of the order in which concretization rules are selected.

As a related technique, in Non-Patent Document 1 (Takashi Maruyama et al.: “Accelerated Search for Search-Based Network Design Generation Scheme with Reinforcement Learning”, IEICE technical report, vol. 118, no. 483, ICM2018-71, pp. 123-128, March 2019), a technique is disclosed for appropriately selecting the concretization rules and appropriately determining the suitability of the order in which concretization rules are selected using reinforcement learning.

However, with the technique disclosed in Non-Patent Document 1, when the number of types of components included in the system configuration increases, the number of component combinations increases, and as a result, the number of types of concrete system configurations also increases. Therefore, a tremendous amount of time is needed to perform reinforcement learning for designing a large-scale system.

### SUMMARY OF THE INVENTION

An example object of the present disclosure is to reduce the time needed to perform reinforcement learning for designing a large-scale system.

In order to achieve the example object described above, a system design learning apparatus according to an example aspect includes:
a design unit that, with respect to a system requirement that is information representing a configuration of a system including an abstract part, executes concretization processing in which the abstract part is converted to a concrete part, generates a concrete system configuration that is information representing a configuration of the system that does not include an abstract part, and generates configuration path information representing a process of generating the concrete system configuration from the system requirement;
a reward setting unit that sets rewards to the system requirement, a system configuration idea generated in a process of the concretization processing, and the concrete system configuration that are included in the configuration path information, respectively;
a conversion unit that generates abstract configuration path information by abstractizing the configuration path information;
a learning data generation unit that generates learning data by associating the rewards with an abstractized system requirement, an abstractized system configuration idea, and an abstractized concrete system configuration that are included in the abstract configuration path information, respectively; and
a learning unit that learns a design method of the system based on the learning data.

Also, in order to achieve the example object described above, a system design learning method according to an example aspect for an information processing apparatus to carry out:
with respect to a system requirement that is information representing a configuration of a system including an abstract part, executing concretization processing in which the abstract part is converted to a concrete part, generating a concrete system configuration that is information representing a configuration of the system that does not include an abstract part, and generating configuration path information representing a process of generating the concrete system configuration from the system requirement;
setting rewards to the system requirement, a system configuration idea generated in a process of the concretization processing, and the concrete system configuration that are included in the configuration path information, respectively;
generating abstract configuration path information by abstractizing the configuration path information;
generating learning data by associating the rewards with an abstractized system requirement, an abstractized system configuration idea, and an abstractized concrete system configuration that are included in the abstract configuration path information, respectively; and
learning a design method of the system based on the learning data.

Furthermore, in order to achieve the example object described above, a computer-readable recording medium according to an example aspect includes a program recorded on the computer-readable recording medium, the program including instructions that cause the computer to carry out:
with respect to a system requirement that is information representing a configuration of a system including an abstract part, executing concretization processing in which the abstract part is converted to a concrete part, generating a concrete system configuration that is information representing a configuration of the system that does not include an abstract part, and generating configuration path information representing a process of generating the concrete system configuration from the system requirement;
setting rewards to the system requirement, a system configuration idea generated in a process of the concretization processing, and the concrete system configuration that are included in the configuration path information, respectively;
generating abstract configuration path information by abstractizing the configuration path information;
generating learning data by associating the rewards with an abstractized system requirement, an abstractized system configuration idea, and an abstractized concrete system configuration that are included in the abstract configuration path information, respectively; and
learning a design method of the system based on the learning data.

As described above, according to the present disclosure, the time needed to perform reinforcement learning for designing a large-scale system can be reduced.

### BRIEF DESCRIPTION OF THE DRAWINGS

FIG. 1 is a diagram for describing automated design of the face authentication system.

FIG. 2 is a diagram for describing the data structure of component information.

FIG. 3 is a diagram for describing the data structure of the system requirement.

FIG. 4 is a diagram for describing the concretization rules.

FIG. 5 is a diagram for describing the data structure of the concretization rules.

FIG. 6 is a diagram illustrating an example of the system design learning apparatus of the first example embodiment.

FIG. 7 is a diagram illustrating an example of the system including the system design learning apparatus of the first example embodiment.

FIG. 8 is a diagram for describing an example of operations of the system design learning apparatus of the first example embodiment.

FIG. 9 is a diagram for describing an example of operations of the functional requirement learning.

FIG. 10 is a diagram for describing an example of operations for generating the configuration path.

FIG. 11 is a diagram for describing an example of the data structure of the search tree information.

FIG. 12 is a diagram for describing an example of the search tree.

FIG. 13 is a diagram for describing an example of the data structure of the configuration path.

FIG. 14 is a diagram for describing an example of operations of the reward setting.

FIG. 15 is a diagram for describing an example of the operations of updating reward information.

FIG. 16 is a diagram for describing an example of operations for generating an abstract configuration path.

FIG. 17 is a diagram for describing an example of the data structure of the abstract configuration path.

FIG. 18 is a diagram for describing an example of operations for generating abstract configurations.

FIG. 19 is a diagram for describing an example of the data structure of the type definition information.

FIG. 20 is a diagram for describing an example of operations for deciding rewards and generating learning data.

FIG. 21 is a diagram for describing an example of operations for performing learning.

FIG. 22 is a diagram illustrating an example of the system design learning apparatus of the second example embodiment.

FIG. 23 is a diagram for describing an example of operations of the system design learning apparatus of the second example embodiment.

FIG. 24 is a diagram for describing an example of operations of the non-functional requirement learning.

FIG. 25 is a diagram for describing an example of the operations for generating the configuration path.

FIG. 26 is a diagram for describing an example of the data structure of the performance information.

FIG. 27 is a diagram for describing an example of the operations for deciding rewards and generating learning data.

FIG. 28 is a diagram for describing an example of a computer that realizes the system design learning apparatus of the first to third example embodiments.

FIG. 29 is a diagram illustrating an example of the system design learning apparatus of the third example embodiment.

FIG. 30 is a diagram for describing an example of operations of the system design learning apparatus of the third example embodiment.

FIG. 31 is a diagram for describing an example of the operations of the non-functional requirement learning.

FIG. 32 is a diagram for describing an example of operations for generating the abstract configuration path.

FIG. 33 is a diagram for describing an example of operations for generating abstract configurations.

FIG. 34 is a diagram for describing an example of the data structure of non-functional requirement influencing type information.

### EXEMPLARY EMBODIMENT

First, an outline will be described for facilitating understanding of the example embodiments described below.

### (System Design)

A case of designing a face authentication system will be described as an example. When designing a face authentication system, first, a designer creates a system requirement for the face authentication system.

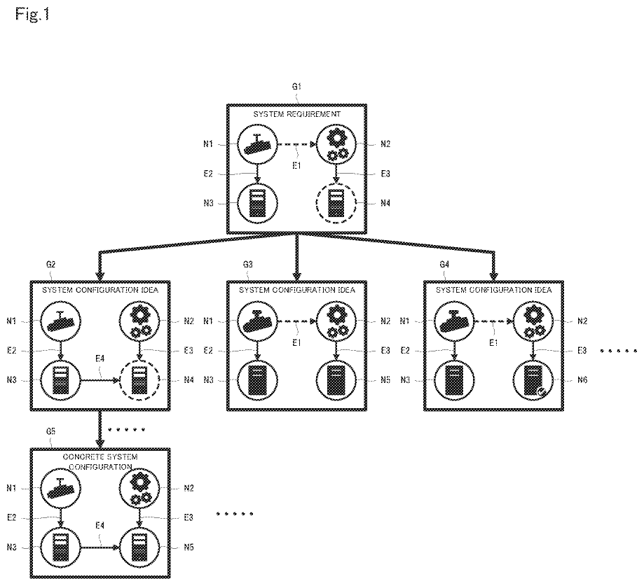

FIG. 1 is a diagram for describing automated design of the face authentication system. A graph G1 in FIG. 1 is a graph representing the configuration of a system requirement R1 for the face authentication system. The graph G1 in FIG. 1 is represented by using nodes N1 to N4 and edges E1 to E3.

The node N1 represents a concrete camera function (solid line circle), the node N2 represents a concrete face authentication function (solid line circle), the node N3 represents a concrete server computer function (solid line circle), and the node N4 represents an abstract server computer function (broken line circle). Also, the edge E1 represents an abstract HTTP communication function (broken line arrow), and the edges E2 and E3 represent a concrete join (belonging) function (solid line arrow).

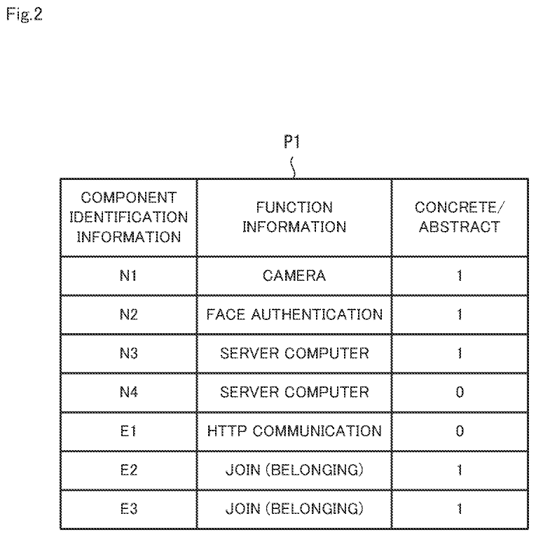

FIG. 2 is a diagram for describing the data structure of component information. In the component information P1 shown in FIG. 2, for each piece of component identification information for identifying a node or edge, function information representing the function of the node or edge is associated with information (concrete (1)/abstract (0)) indicating that the node or edge is a concrete component or an abstract component.

In the example in FIG. 2, component identification information “N1”, function information “camera”, and information “1” indicating that the node is concrete are associated with each other. Each of the pieces of component identification information “N2” to “N4” and “E1” to “E3” are similarly associated with function information and information indicating that the node or edge is concrete or abstract.

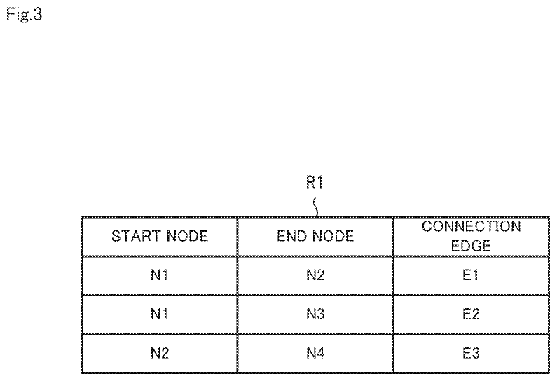

FIG. 3 is a diagram for describing the data structure of the system requirement. The system requirement R1 corresponding to the graph G1 shown in FIG. 1 is represented using two nodes (start node and end node) and an edge (connection edge) connecting the two nodes, as shown in FIG. 3.

Specifically, the system requirement R1 is information in which component identification information for identifying a node (start node) that is a start point, component identification information for identifying a node (end node) that is an end point, and component identification information for identifying an edge (connection edge) that connects the two nodes are associated with each other.

Note that, in FIGS. 1 to 3 described above, the graph, component information, and system requirement are described using the graph G1, component information P1, and system requirement R1, but the graph, component information, and system requirement are not limited to the graph G1, component information P1, and system requirement R1.

Next, in automated design, abstract parts are converted into concrete parts. In the example in FIG. 1, it is shown that graphs G2, G3, G4, . . . corresponding to a plurality of system configuration ideas R2, R3, and R4, as shown in FIG. 1, are derived from the graph G1 corresponding to the system requirement R1 by performing concretization based on concretization rules.

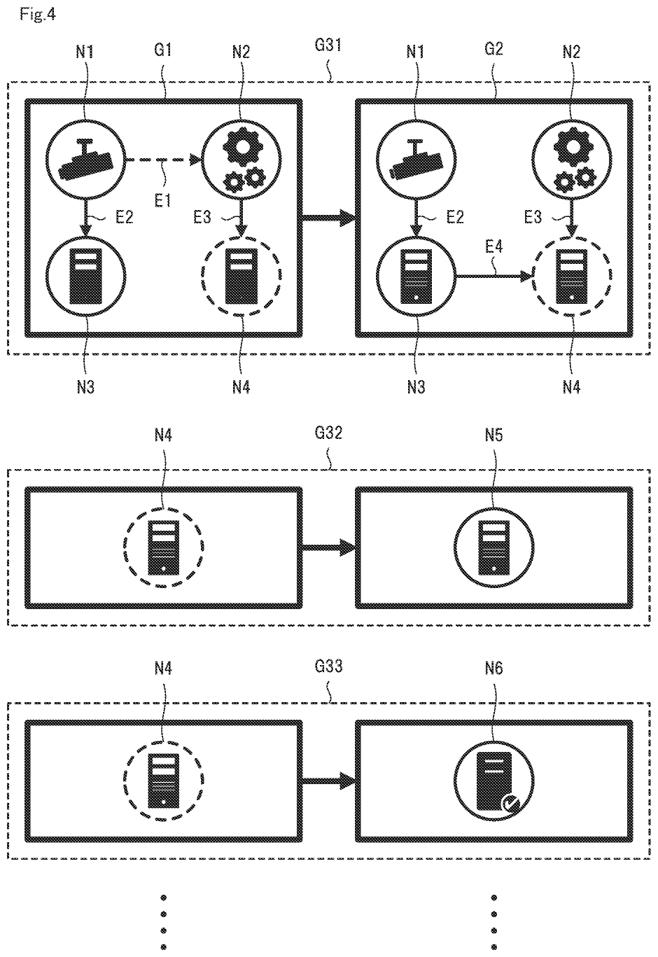

FIG. 4 is a diagram for describing the concretization rules. In FIG. 4, graphs G31, G32, G33, . . . that are obtained by representing the plurality of concretization rules with graphs are shown.

The graph G31 is a graph representing a concretization rule Rule1 used to convert the graph G1 shown in FIG. 1 to the graph G2 shown in FIG. 1. The graph G32 is a graph representing a concretization rule Rule2 used to convert the graph G1 shown in FIG. 1 to the graph G3 shown in FIG. 1 (to convert the node N4 to a node N5). The graph G33 is a graph representing a concretization rule Rule3 used to convert the graph G1 shown in FIG. 1 to the graph G4 shown in FIG. 1 (to convert the node N4 to a node N6).

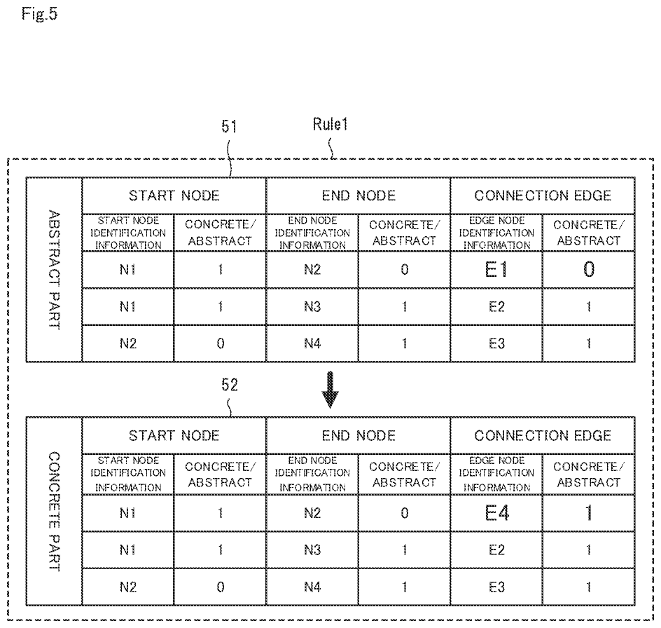

FIG. 5 is a diagram for describing the data structure of the concretization rules. The concretization rule Rule1 shown in FIG. 5 corresponds to the graph G31. Also, the concretization rule Rule1 includes detection information 51 used to detect abstract parts and conversion information 52 for converting abstract parts to concrete parts.

Note that, although not illustrated, concretization rules Rule2, Rule3, . . . corresponding to the graphs G32, G33, . . . exist for the graphs G32, G33, . . . as well.

When the graphs G2, G3, and G4 are derived from the graph G1 shown in FIG. 1, first, the system requirement R1 is compared with a plurality of pieces of detection information (abstract parts of concretization rules), and detection information that matches the abstract parts included in the system requirement R1 is detected.

Next, the detected abstract parts of the system requirement R1 are changed to conversion information (concrete parts of concretization rules) using detection information corresponding to the detected abstract components. Because the system requirement R1 matches the detection information 51 of the concretization rule Rule1, in the conversion to the graph G2, replacement of the detection information 51 with the conversion information 52 of the concretization rule Rule1 is performed (converted).

As a result, the edge E1 is deleted from the system requirement R1, the edge E4 is added, and the system configuration idea R2 (not shown) corresponding to the graph G2 is generated. Note that system configuration ideas R3 and R4 (not shown) corresponding to the graphs G3 and G4, respectively, are also generated.

Next, for each of the plurality of generated system configuration ideas, abstract parts of the system configuration ideas are further converted to concrete parts using the concretization rules. Also, when a system configuration idea is generated, the aforementioned concretization processing is repeated. When system configuration ideas cease to be generated, only concrete system configurations that do not include abstract components are longer present, and the concretization processing is stopped (automated design is ended).

Incidentally, when the system requirement and system configuration ideas are concretized, a plurality of concretization rules are used, and thus the derived system configuration ideas and concrete system configurations change depending on the selected concretization rule and the order in which concretization rules are selected. That is, depending on the order in which concretization rules are selected, a system configuration idea and a concrete system configuration that have different configurations are derived.

Also, as the number of concretization rules to be applied increases, the number of system configuration ideas and concrete system configurations that are to be generated increases tremendously. Also, the different concrete system configurations may include a concrete system configuration that does not satisfy the system requirement. Therefore, the concrete system configurations cannot be efficiently derived.

Also, in order to efficiently derive the concrete system configuration, it is important to appropriately determine which of the concretization rules are to be applied and the suitability of the order of concretization rules to be applied.

Therefore, evaluation values are obtained for system configuration ideas that are generated by executing concretization processing using a learning model acquired by machine learning, and the system configuration idea with the largest evaluation value is selected from among the system configuration ideas. As a result of repeating the concretization processing using the learning model, in this way, the concrete system configurations can be efficiently derived.

### First Example Embodiment

Hereinafter, a first example embodiment will be described with reference to the drawings. Note that, in the drawings described below, the elements that have the same or corresponding functions are given the same reference numerals and description thereof may not be repeated.

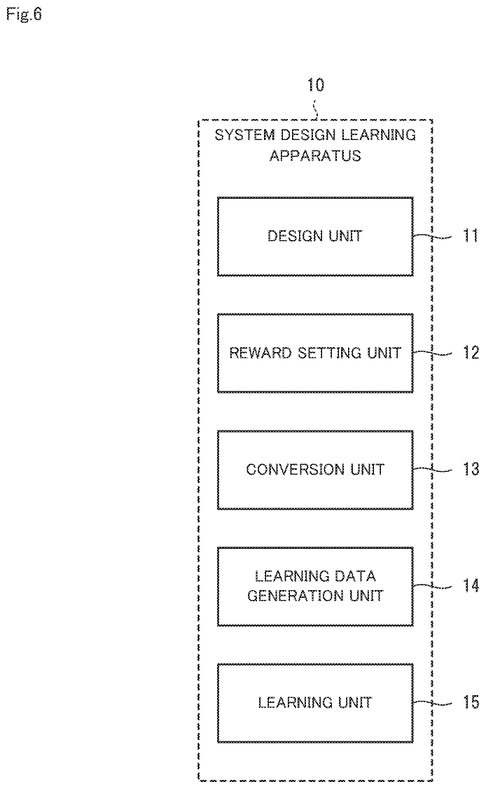

The configuration of a system design learning apparatus 10 in the first example embodiment will be described using FIG. 6. FIG. 6 is a diagram illustrating an example of the system design learning apparatus of the first example embodiment.

### [Apparatus Configuration]

The system design learning apparatus 10 shown in FIG. 6 is an apparatus that learns about design regarding functional requirements of an ICT system. The system design learning apparatus 10 includes a design unit 11, a reward setting unit 12, a conversion unit 13, a learning data generation unit 14, and a learning unit 15.

The design unit 11 executes concretization processing for converting abstract parts to concrete parts with respect to a system requirement, which is information representing the configuration of a system including abstract parts, generates a concrete system configuration, which is information representing the configuration of a system that does not include abstract parts, and generates configuration path information that represents the process of generating the concrete system configuration from the system requirement.

The reward setting unit 12 sets a reward for each of the system requirement, the system configuration ideas generated in a process of the concretization processing, and the concrete system configuration, which are included in the configuration path information. Also, the reward setting unit 12 sets rewards for learning a system design method based on the functional requirements.

The conversion unit 13 generates abstract configuration path information by abstractizing the configuration path information. Specifically, the conversion unit 13 converts type information representing the types of components included in the system requirement, system configuration ideas, and concrete system configurations that are included in the configuration path information to abstract type information representing abstract types based on type definition information for converting types to abstract types, and with this generates abstract configuration path information.

The learning data generation unit 14 generates learning data by associating a reward with each of the abstractized system requirement, abstractized system configuration ideas, and an abstractized concrete system configurations that are included in the abstract configuration path information. The learning unit 15 learns a system design method based on the functional requirements, based on the learning data.

As described above, in the first example embodiment, the time needed to perform reinforcement learning regarding large-scale system design can be reduced.

### [System Configuration]

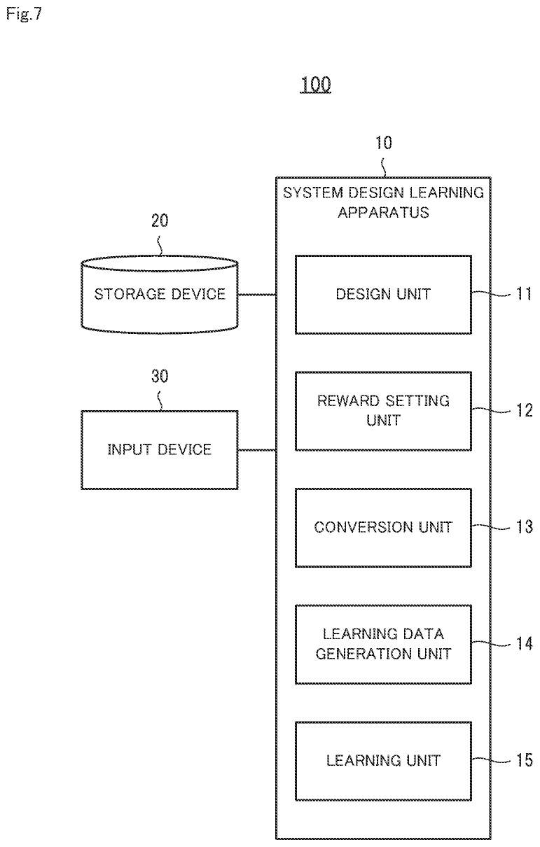

Next, the configuration of the system design learning apparatus 10 in the first example embodiment will be more specifically described using FIG. 7. FIG. 7 is a diagram illustrating an example of the system including the system design learning apparatus of the first example embodiment.

A system 100 includes at least the system design learning apparatus 10, a storage device 20, and an input device 30. The system design learning apparatus 10, the storage device 20, and the input device 30 are communicably connected via a network.

The system design learning apparatus 10 is a CPU (Central Processing Unit), a programmable device such as an FPGA (Field-Programmable Gate Array), or a GPU (Graphics Processing Unit), or a circuit on which at least one of the devices is mounted, or an information processing apparatus such as a server computer, a personal computer, or a mobile terminal.

The storage device 20 is a database, a server computer, a circuit including a memory, or the like. The storage device 20 stores various types of information described below. In the example in FIG. 2, one storage device 20 is provided outside the system design learning apparatus 10, but a plurality of storage devices 20 may also be provided inside or outside of the system design learning apparatus 10.

The input device 30 includes devices such as a keyboard, a mouse, and a touch panel, for example. The input device 30 is used to operate the system design learning apparatus 10, an output device 40, and the like.

The communication network is an ordinary communication network constructed using a communication line such as the Internet, a LAN (Local Area Network), a dedicated line, a telephone line, an intranet, a mobile communication network, Bluetooth (registered trademark), or Wi-Fi (Wireless Fidelity) (registered trademark).

### [Apparatus Operations]

Operations of the system design learning apparatus in the first example embodiment will be described. In the following description, the drawings are referred to as appropriate.

Furthermore, in the first example embodiment, a system design learning method is implemented by causing the system design learning apparatus to operate. Accordingly, the following description of operations of the system design learning apparatus replaces the description of the system design learning method in the first example embodiment.
The operations of the system design learning apparatus will be described.

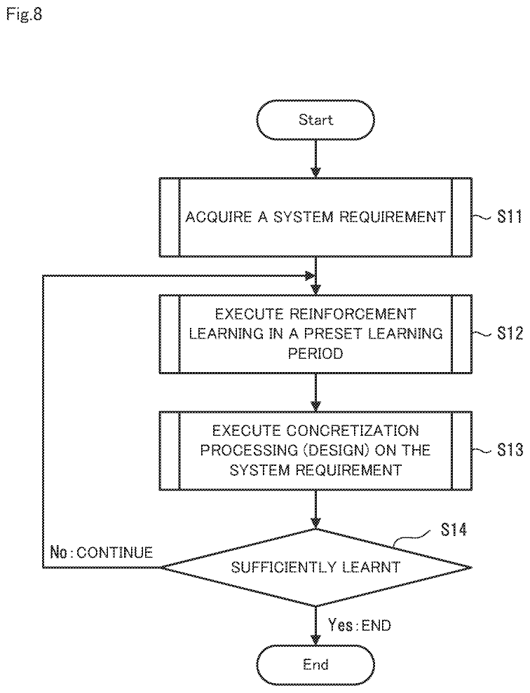

FIG. 8 is a diagram for describing an example of operations of the system design learning apparatus of the first example embodiment. First, the system design learning apparatus 10 acquires a learning-target system requirement from the storage device 20 (step S11).

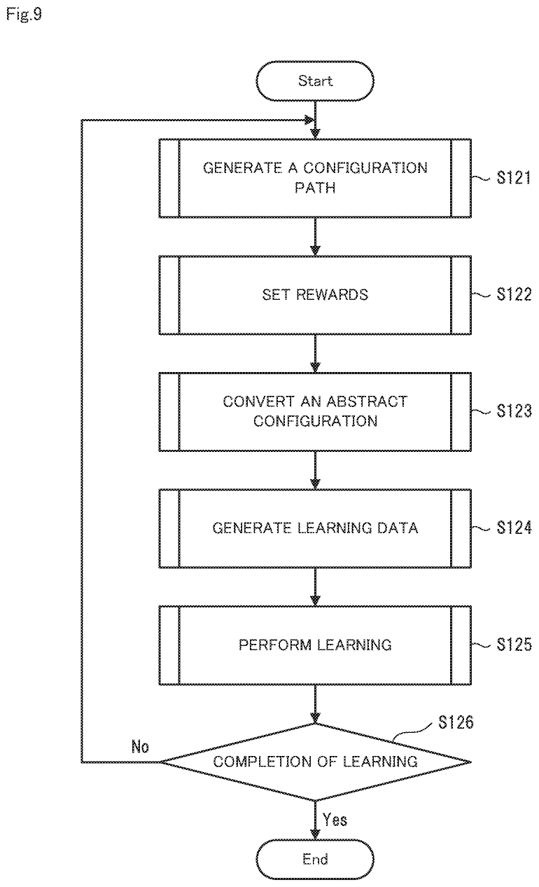

Next, the system design learning apparatus 10 executes reinforcement learning in a preset learning period using the system requirement for which learning is performed (step S12). The details of step S12 will be described later with reference to FIG. 9.

The learning period is determined by experimentation or simulation, for example. Also, the learning period may be replaced with a number of learning instances. When a neural network is used in the reinforcement learning, for example, the number of learning instances is the number of times a weight of the neural network has been updated. Note that the period in which learning is performed is not limited to being defined by the learning period and the number of learning instances.

Next, the system design learning apparatus 10 executes concretization processing (design) on the system requirement using a current learning model of functional requirements (step S13). For example, when a neural network is used in the reinforcement learning, the learning model of the functional requirements refers to the neural network.

The concretization processing (design) is processing for concretizing abstract parts (components) included in the system requirement. Note that the design method described in Patent Document 1 is suitable for the concretization processing (design), for example, but the concretization processing (design) is not limited to the method of Patent Document 1.

Next, if it is determined that the functional requirements have been sufficiently learnt (step S14: Yes) based on the result in step S13, the system design learning apparatus 10 ends the processing in step S12. Also, if it is determined that the functional requirements have not been sufficiently learnt (step S14: No), the system design learning apparatus 10 repeats (continues) the processing in steps S12 and S13 until it is determined that the functional requirements have been sufficiently learnt.

When the processing in step S13 is executed as per/according to the design method of Patent Document 1, the determination in step S14 is determined to be sufficient if the number of search steps is a preset threshold A or less, for example. Also, it may be determined to be sufficient if the number of search steps is a preset threshold B or less a specific number of times successively in a previously executed step S13. Note that the determination in step S14 is not limited to the aforementioned determination.

Note that the aforementioned number of search steps depends on the design method in step S13. Also, the number of search steps is the number of system configuration ideas actually conceived during design. Also, the number of search steps may also be rephrased as the number of concretization rules that have actually been applied during design.

The method of determining the thresholds A and B need only be a method with which it can be determined that the number of steps needed for design is sufficiently small. For example, the smallest number of steps needed for searching is calculated in advance, and the thresholds A and B may be set to values obtained by adding some margin (e.g., 10%) to the smallest number of steps. Alternatively, the number of search steps executed during a time period that is practically no problem (e.g., 10 minutes) is calculated in advance, and may be set to the thresholds A and B.
Operations of functional requirement learning (step S12) will be described.

FIG. 9 is a diagram for describing an example of operations of the functional requirement learning. In the functional requirement learning, a design method regarding functional requirements of an ICT system is learnt.

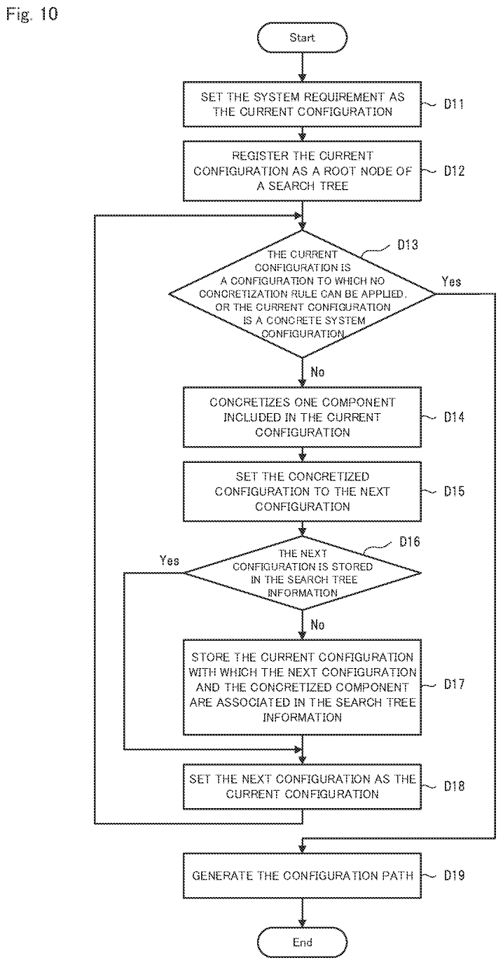

First, the design unit 11 generates a configuration path using system requirement (step S121). The details of step S121 will be described later with reference to FIG. 10.

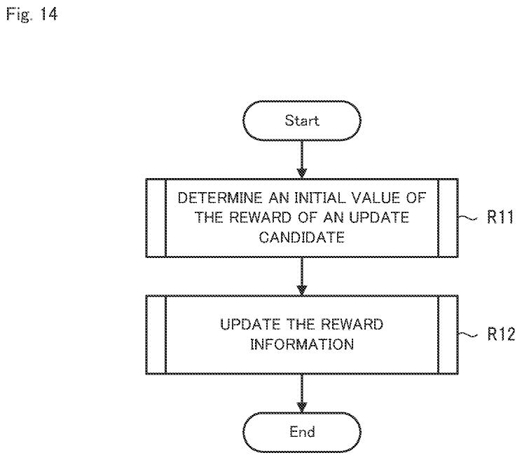

Next, the reward setting unit 12 sets rewards for each of the system configurations (aforementioned system requirement, system configuration ideas, or concrete system configurations) of the configuration path generated in step S121 (step S122). The details of step S122 will be described later with reference to FIG. 14.

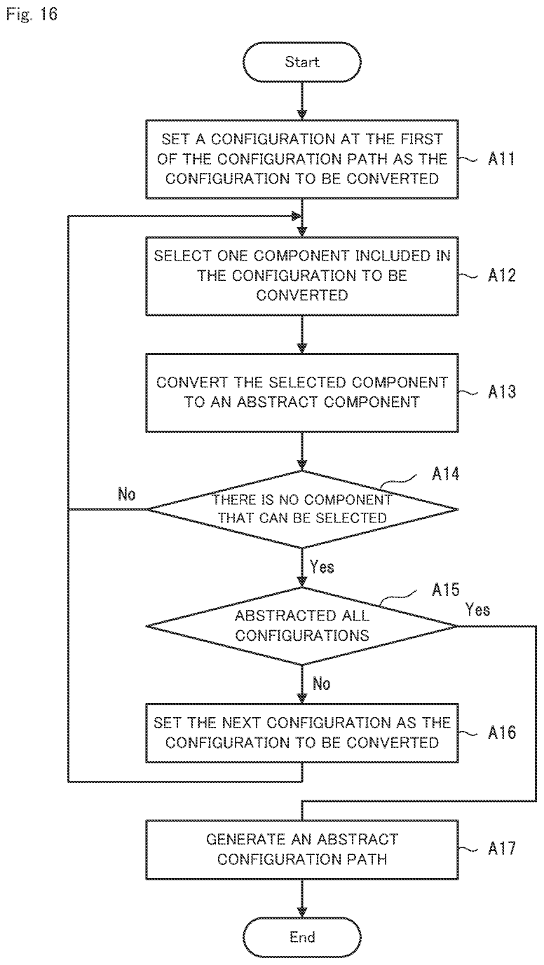

Next, the conversion unit 13 converts each of the system configurations of the configuration path generated in step S121 to an abstract configuration by executing abstraction processing thereon (step S123). The details of step S123 will be described later with reference to FIG. 16.

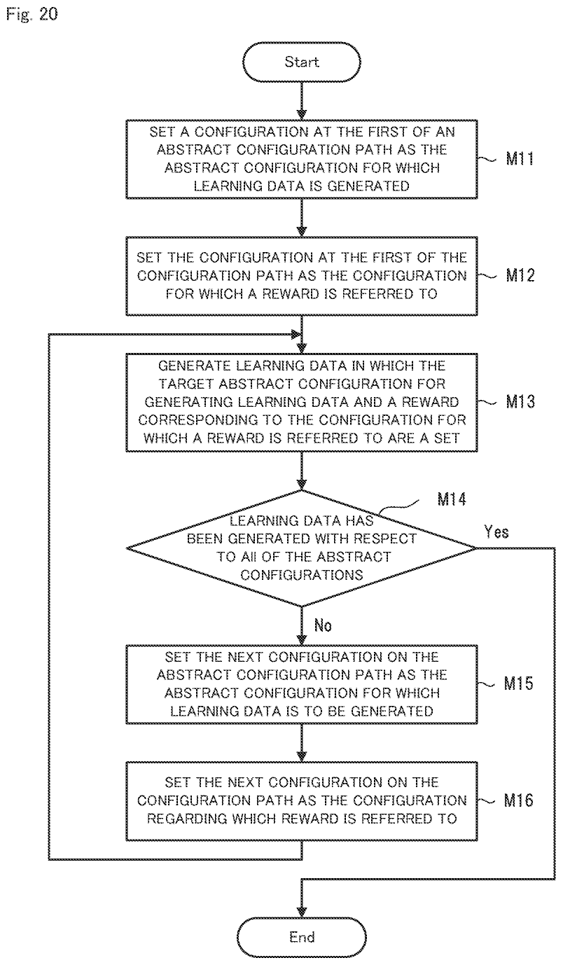

Next, the learning data generation unit 14 generates learning data by associating the abstract configurations with rewards of the configuration path, and stores the generated learning data in the storage device 20 (step S124). The details of step S124 will be described later with reference to FIG. 20.

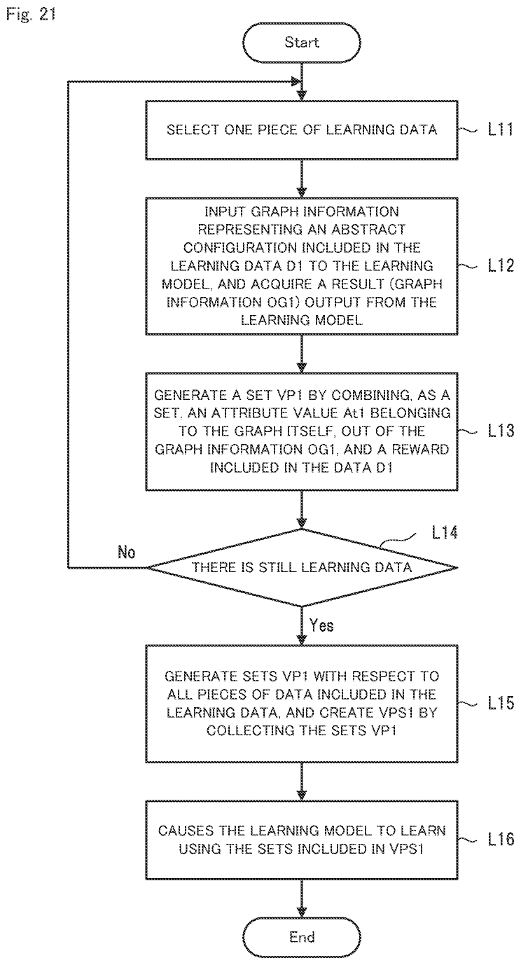

Next, the learning unit 15 performs learning based on the learning data (step S125). The details of step S125 will be described later with reference to FIG. 21.

In this way, steps S121 to S125 are repeated in the preset learning period (step S126).
Operations for generating the configuration path (step S121) will be described.

FIG. 10 is a diagram for describing an example of operations for generating the configuration path.

First, the design unit 11 sets the system requirement as the current configuration (system configuration) (step D11). Next, the design unit 11 registers the current configuration as a root node of a search tree (step D12). Specifically, the design unit 11 stores system requirement identification information for identifying the current configuration (system requirement) in search tree information as the root node.

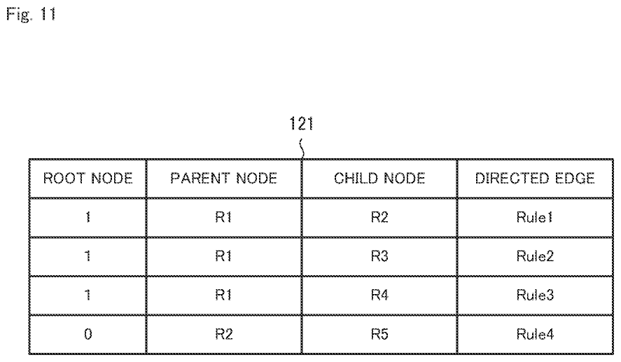

FIG. 11 is a diagram for describing an example of the data structure of the search tree information. In the example of FIG. 11, system requirement identification information “R1” associated with the system requirement R1 stored in the storage device 20 is stored in a “parent node” of search tree information 121, and also information indicating that the system requirement R1 is a root node is stored in the “root node”. Note that, in the example in FIG. 11, “1” is stored as information indicating to be a root node.

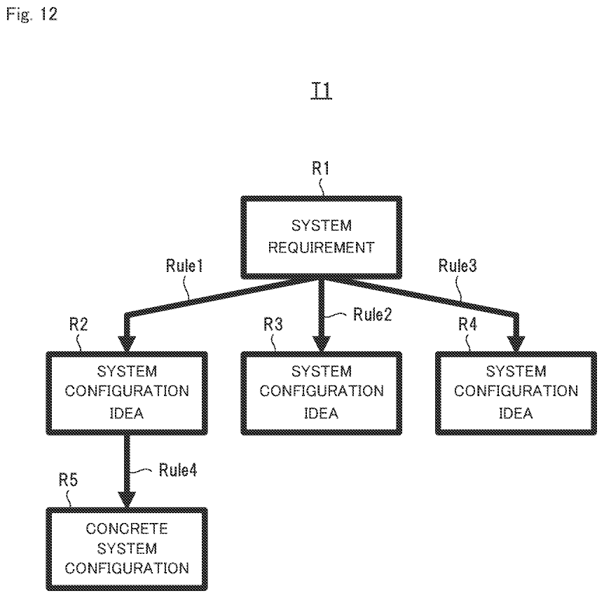

FIG. 12 is a diagram for describing an example of the search tree. The search tree can be represented by a graph (search tree T1), as shown in FIG. 12. The root node (system requirement R1) shown in FIG. 12 corresponds to R1 in FIG. 12.

Next, if the current configuration is a configuration to which no concretization rule can be applied, or the current configuration is a concrete system configuration (step D13: Yes), the design unit 11 shifts the processing to the processing in step D19. Also, if a concretization rule that can be applied to the current configuration is present (step D13: No), the design unit 11 repeats the processing from step D14 to step D18.

Next, the design unit 11 concretizes one component included in the current configuration by executing concretization processing (step D14). Next, the design unit 11 sets the configuration (system configuration idea) concretized in step D14 to the next configuration (step D15).

Next, if the next configuration (concretized configuration (system configuration idea)) is not stored in the search tree information (step D16: No), the design unit 11 shifts the processing to step D17. Also, if the next configuration (concretized configuration (system configuration idea)) is stored in the search tree information (step D16: Yes), the design unit 11 shifts the processing to step D18.

Next, the design unit 11 stores the current configuration with which the next configuration and the concretized component are associated in the search tree information, in which the node representing the current configuration is a parent node, the next configuration (concretized configuration) is a child node, and the edge representing the concretized component (concrete component in the concretization rule) is a directed edge (step D17).

For example, when system configuration idea R2 is generated from the system requirement R1 which is the current configuration, system configuration idea identification information “R1” corresponding to the system requirement R1 of the search tree information 121, system configuration idea identification information “R2” corresponding to a system configuration idea R2 generated by the concretization processing, and concretization rule identification information “Rule1” corresponding to the concretization rule used in the concretization processing are stored in association with each other, as shown in FIG. 11.

Also, regarding the current configuration, when a concrete system configuration R5 is generated from the system configuration idea R2, system configuration idea identification information “R2” of the search tree information 121, concrete system configuration identification information “R5” associated with a concrete system configuration generated by the concretization processing, and concretization rule identification information “Rule4” associated with the concretization rule used in the concretization processing are stored in association with each other, as shown in FIG. 11.

Next, the design unit 11 sets the next configuration as the current configuration (step D18).

Next, the design unit 11 generates, from the system configuration (system requirement, system configuration idea, and concrete system configuration) that appeared in the processing in steps D11 to D18 described above, a path (configuration path information in which the configuration is stored in chronological order (configuration path)) from the system requirement to the generation of the current concrete system configuration (step D19).

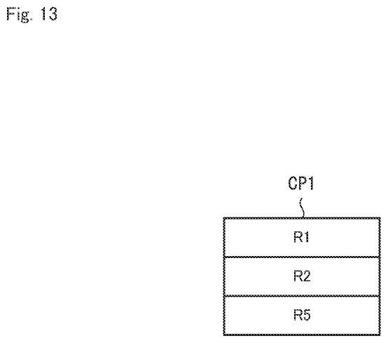

FIG. 13 is a diagram for describing an example of the data structure of the configuration path. In the configuration path CP1 shown in FIG. 13, the system requirement “R1”, system configuration idea “R2”, and concrete system configuration “R5” shown in FIGS. 11 and 12 are shown in this order.
Operations of the reward setting (step S122) will be described.

FIG. 14 is a diagram for describing an example of operations of the reward setting.

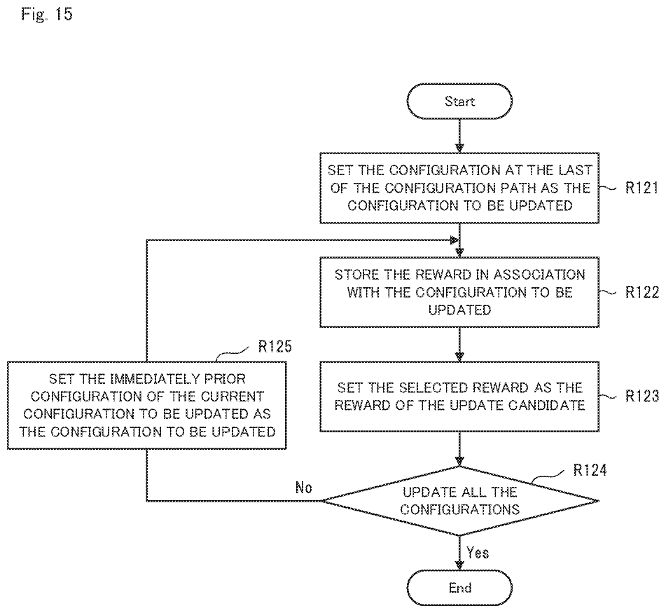

First, the reward setting unit 12 determines an initial value of the reward of an update candidate (step R11). Next, the reward setting unit 12 updates the reward records of system configurations on the configuration path (step R12). The details of step R12 will be described later with reference to FIG. 15.

In step R11, the reward setting unit 12 sets, as the initial value of the reward of the update candidate, if the final configuration of the configuration path is a concrete system configuration, “1” as reward information representing the reward of the concrete system configuration, for example, and if the final configuration of the configuration path is not a concrete system configuration, “0” as reward information representing the reward corresponding to the final configuration, for example.

Note that the reward of an update candidate is a value used when updating a value of the reward obtained by each system configuration on the configuration path in step R12.

Note that, in the case of the example in FIG. 13, the final configuration on the configuration path CP1 is the concrete system configuration R5, and therefore, in the processing in step R12, “R5” representing the concrete system configuration in the configuration path CP1 is associated with reward information “1”.
Operations of updating rewards (step R12) will be described in more detail.

FIG. 15 is a diagram for describing an example of the operations of updating reward information.

First, the reward setting unit 12 sets the configuration (system configuration) at the tail (last) of the configuration path as the configuration to be updated (system configuration) (step R121). Next, the reward setting unit 12 compares the reward associated with the configuration to be updated with the reward of the update candidate, selects the larger reward, and stores the selected reward in association with the configuration to be updated (step R122). Next, the reward setting unit 12 sets the reward selected in step R122 (larger one in the comparison) as the reward of the update candidate (step R123).

Next, if the reward update processing has not been performed on all of the configurations on the configuration path (reward update processing has not been performed up to the configuration (system configuration) at the head (first) of the configuration path) (step R124: No), the reward setting unit 12 sets the immediately prior configuration to the current configuration in the configuration path as the configuration to be updated (step R125), and shifts the processing to step R122.

Also, if the reward update processing has been performed on all of the configurations in the configuration path (update processing has been performed up to the configuration (system configuration) at the head (first) in the configuration path) (step R124: Yes), the reward setting unit 12 ends the processing in step R12.

Specifically, regarding the reward of the update candidate in step R122, the reward associated with the configuration to be updated is compared with the reward of the update candidate, here if no former reward is present (if not associated) before comparison, the former reward is regarded as being “0”. Then, after comparison, the reward is updated such that the larger reward is the reward associated with the configuration to be updated and the reward of the update candidate. Thereafter, the configuration to be updated is updated, and this processing is repeated.

For example, at first, no reward is associated with any configuration, and therefore in the example in FIG. 13, “R5” is the first configuration of the update candidate in step R121, “R5” is not yet associated with a reward, and therefore the value thereof is regarded as being “0”. In this case, regarding the reward of the update candidate, since the reward is initialized to “1” in step R11, “0” and “1” are compared, and because “1” is larger, “R5” is associated with a reward of “1”.

Next, the configuration of the update candidate is set to “R2”, and processing similar to the processing described above is repeatedly executed. Thereafter, moreover, the configuration of the update candidate is set to “R1”, and processing similar to the processing described above is repeated.

As another example, if processing is started with the first configuration of the update candidate (configuration that is not a concrete system configuration), and is not a concrete configuration, the reward of the update candidate is initialized to “0”, and if the next configuration is associated with a reward of “1”, “0” and “1” are compared, and because “1” is larger, the value of the reward of the update candidate is updated to “1”.

Specifically, in the processing in step R12, from the design performed in step S121, data (reward) is generated for learning evaluation values of the configurations “R2” and “R1” in the process of designing based on the evaluation value of the configuration “R5” at the end of designing. Here, if larger data (reward) has been obtained in the past, this data is prioritized and is compared with the reward stored in association with the configuration, and the larger reward remains.

The reason why the larger reward remains and is caused to propagate upward (“R1” viewed from “R2”) is because it is understood that a transition from “R1” to “R2” is possible. The estimation of a reward obtained when best selection has been continuously performed is desired to be learned, and it is understood that the transition from “R1” to “R2” is possible if an appropriate concretization rule is applied, and therefore if the reward associated with “R2” is larger, it should propagate to “R1” in priority to the reward of “R5”.

Note that the transition from “R1” to “R2” does not necessarily need to occur, but such a transition is possible. For example, in the example in FIG. 12, a transition to “R3” or “R4” is also possible. Note that to which system requirement transition occurs can be selected by an automated design function, and the larger reward in comparison is to be propagated upward.
Operations of abstractizing a configuration path (step S123) will be described in more detail.

FIG. 16 is a diagram for describing an example of operations for generating an abstract configuration path.

First, the conversion unit 13 sets a configuration (system configuration) at the head (first) of the configuration path as the configuration (system configuration) to be converted (step A11). Next, the conversion unit 13 selects one component from all of the components included in the configuration to be converted (step A12).

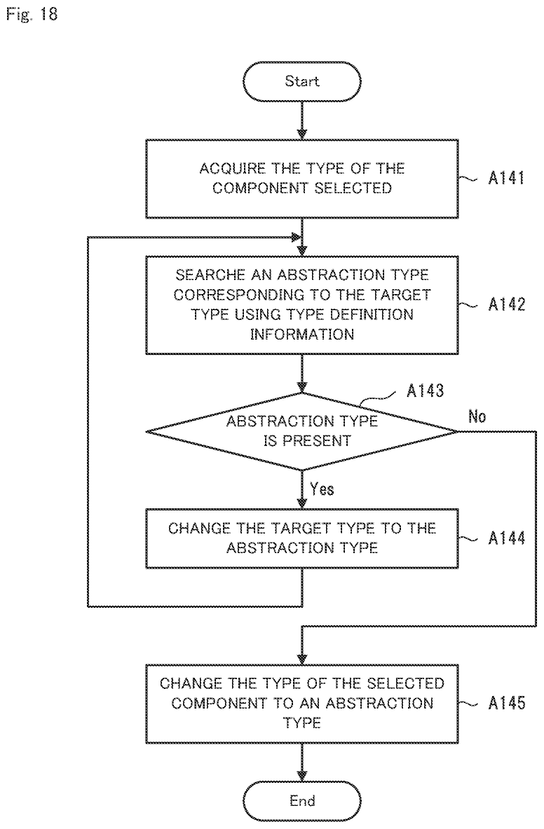

Next, the conversion unit 13 converts the selected component to an abstract component (step A13). The details of step A13 will be described later with reference to FIG. 18.

Next, if there is no component that can be selected (step A14: Yes), the conversion unit 13 shifts the processing to step A15. Also, if there is a component that can be selected (step A14: No), the conversion unit 13 shifts the processing to step A12, and repeats the processing in steps A12 and A13 until no unselected component remain.

Next, if the abstraction processing has not been performed on all of the configurations (system configurations) on the configuration path (if abstraction processing has not been performed up to the configuration (system configuration) at the tail (last) in the configuration path) (step A15: No), the conversion unit 13 sets the next configuration (system configuration) on the configuration path as the configuration to be converted (step A16). Next, the conversion unit 13 shifts the processing to step A12.

Also, when the abstraction processing has been performed on all of the configurations in the configuration path (when abstraction processing has been performed up to the configuration (system configuration) at the tail (last) in the configuration path) (step A15: Yes), the conversion unit 13 executes the processing in step A17. That is, the conversion unit 13 stores all of the abstract configurations generated in the aforementioned conversion processing in steps A11 to A16 (abstractized system configurations) in chronological order, and generates an abstract configuration path (step A17).

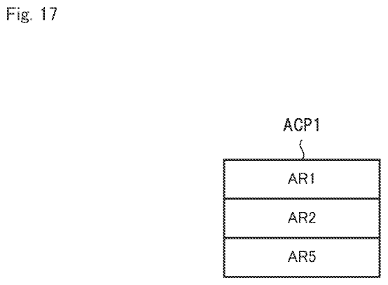

FIG. 17 is a diagram for describing an example of the data structure of the abstract configuration path. The abstract configuration path ACP1 shown in FIG. 17 is obtained by abstractizing the configuration path CP1 shown in FIG. 13. Note that the abstractized system requirement “AR1”, system configuration idea “AR2”, and concrete system configuration “AR5” on the abstract configuration path ACP1 are shown in the order of the system requirement “R1”, system configuration idea “R2”, and concrete system configuration “R5” shown in FIGS. 11 and 12.
·Operations of converting to abstract components (step A13) will be described in more detail.

FIG. 18 is a diagram for describing an example of operations for generating abstract configurations.

First, the conversion unit 13 acquires the type of the component selected in step A13 and sets the type as the target type (step A141). Specifically, the conversion unit 13 acquires the type corresponding to the selected component from component information. For example, function information corresponding to the selected component is acquired by referring to the component information. Alternatively, type information representing the type is also associated with the component identification information and stored in the component information, and the type information corresponding to the selected component may be acquired.

Next, the conversion unit 13 searches an abstraction type corresponding to the target type using type definition information created in advance (step A142). The type definition information is information in which type information representing a type is associated with abstraction type information for abstractizing the type. The type definition information is stored in the storage device 20 or the like.

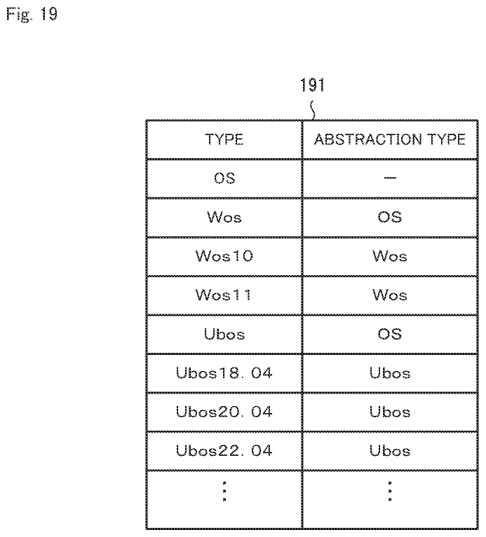

The type information is information representing a function, product name, and the like of a component, for example. The abstraction type information is information in which the function and product name of a component are represented by an upper-level concept, and are abstractized, for example. A detailed description will be given using FIG. 19.

FIG. 19 is a diagram for describing an example of the data structure of the type definition information. In the example of the type definition information 191 in FIG. 19, types (names) of the operating system such as “OS”, “Wos”, “Wos10”, “Wos11”, “Ubos”, “Ubos18.04, “Ubos20.04”, and “Ubos22.04” are stored as the “type” representing the type. Also, in the example in FIG. 19, an expression obtained by abstractizing the operating system stored in the “type” is stored as the “abstraction type” representing the abstraction type.

In the case of “OS”, further abstractization than OS is not possible, and therefore “-” representing no presence is stored in the “abstraction type”. “Wos” represents the type of OS (type is succeeded), and therefore can be abstractized to OS. Therefore, “OS” is stored in the “abstraction type”. “Wos10” represents the type of OS that is Wos and its version, and therefore can be abstractized to Wos. Therefore, “Wos” is stored in the “abstraction type”.

Note that FIG. 19 shows a state of the “abstraction type” in the middle of converting the “type” step by step. That is, in the example in FIG. 19, all of the “abstract types” are ultimately converted to “OS”.

Note that the type definition information is not limited to the operating system, and abstraction types are defined with respect to the types of component other than the operating system. Moreover, in the type definition information, only the abstraction type is associated with a type (only minimum type definition information is shown), but another piece of information may also be associated therewith. For example, information indicating whether a type is concrete or abstract, an attribute value regarding the performance of a component of the type, and information other than these may also be associated.

Next, if the target type is present in the type definition information, and an abstraction type corresponding to the target type is present (step A143: Yes), the conversion unit 13 changes the target type to the abstraction type (step A144), and shifts the processing to step A142. That is, the conversion unit 13 repeats the processing in steps A142 to A144 until the target type can no longer be changed to an abstraction type.

Also, the conversion unit 13 changes the type of the selected component to an abstraction type (step A145). Specifically, the type of component information (e.g., function information) is changed to an abstraction type.
Operations for generating learning data (step S124) will be described in more detail.

FIG. 20 is a diagram for describing an example of operations for deciding rewards and generating learning data.

First, the learning data generation unit 14 sets a configuration (system configuration) at the head (first) of an abstract configuration path as the abstract configuration for which learning data is generated (step M11). Next, the learning data generation unit 14 sets the configuration at the head (first) of the configuration path as the configuration for which a reward is referred to (step M12).

Next, the learning data generation unit 14 generates learning data in which the target abstract configuration for generating learning data and a reward corresponding to the configuration for which a reward is referred to (reward set in step S122) are a set, and stores the generated learning data in the storage device 20 (step M13).

Next, if learning data has not been generated with respect to all of the configurations on the abstract configuration path (if learning data is not generated up to the configuration at the tail (last) of the abstract configuration path (step M14: No), the learning data generation unit 14 shifts the processing to step M15. Also, if learning data has been generated with respect to all of the configurations on the abstract configuration path (if learning data is generated up to the configuration at the tail (last) of the abstract configuration path (step M14: Yes), the learning data generation unit 14 ends the processing for generating the learning data.

Next, the learning data generation unit 14 sets the next configuration on the abstract configuration path as the abstract configuration for which learning data is to be generated (step M15). Next, the learning data generation unit 14 sets the next configuration on the configuration path as the configuration regarding which reward is referred to (step M16).
Operations for learning (step S125) will be described in more detail.

FIG. 21 is a diagram for describing an example of operations for performing learning.

Specific operations with respect to step S125 will be illustrated. The learning model is a GNN (Graph Neural Network) to which graph information in which the nodes and edges in the graph and the graph itself have attribute values is input and that outputs graph information in a similar format.

First, the learning unit 15 selects one piece of learning data DI from the learning data saved in step S124 (step L11). Next, the learning unit 15 inputs graph information representing an abstract configuration included in the learning data DI to the learning model, and acquires a result (graph information OG1) output from the learning model (step L12).

Next, the learning unit 15 generates a set VP1 by combining, as a set, an attribute value At1 belonging to the graph itself, out of the graph information OG1, and a reward included in the data DI (step L13).

Next, if all pieces of the learning data have been selected (step L14: Yes), the learning unit 15 executes the processing in step L15. If all pieces of the learning data have not been selected (step L14: No), the learning unit 15 repeats the processing in steps L11 to L13.

Next, the learning unit 15 respectively generates sets VP1 with respect to all pieces of data included in the learning data, and creates VPS1 by collecting the sets VP1 (step L15).

Next, the learning unit 15 causes the learning model to learn using the sets included in VPS1 such that a loss function is minimized, the loss function being a mean square error of attribute values and rewards (step L16).

### Effects of First Example Embodiment

According to the first example embodiment, with respect to a large-scale system as well, learning about design regarding functional requirements can be performed.

Also, the types of components included in a configuration (system configuration) are abstractized, learning data including an abstract configuration is generated, and learning is performed using the learning data, and as a result, rough evaluation in which an influence due to the difference between components is excluded can be performed. As a result, the time needed to individually learn configurations in which only the components included therein are different can be reduced, and with respect to a large-scale system as well, learning about design regarding functional requirements can be performed.

### [Program]

The program according to the first example embodiment may be a program that causes a computer to execute steps S11 to S14 shown in FIG. 8. By installing this program in a computer and executing the program, the system design learning apparatus and the system design learning method according to the first example embodiment can be realized. Further, the processor of the computer performs processing to function as the design unit 11, the reward setting unit 12, the conversion unit 13, the learning data generation unit 14 and the learning unit 15.

Also, the program according to the first example embodiment may be executed by a computer system constructed by a plurality of computers. In this case, for example, each computer may function as any of the design unit 11, the reward setting unit 12, the conversion unit 13, the learning data generation unit 14 and the learning unit 15.

### Second Example Embodiment

Hereinafter, a second example embodiment will be described with reference to the drawings. Note that, in the drawings described below, the elements that have the same or corresponding functions are given the same reference numerals and description thereof may not be repeated.

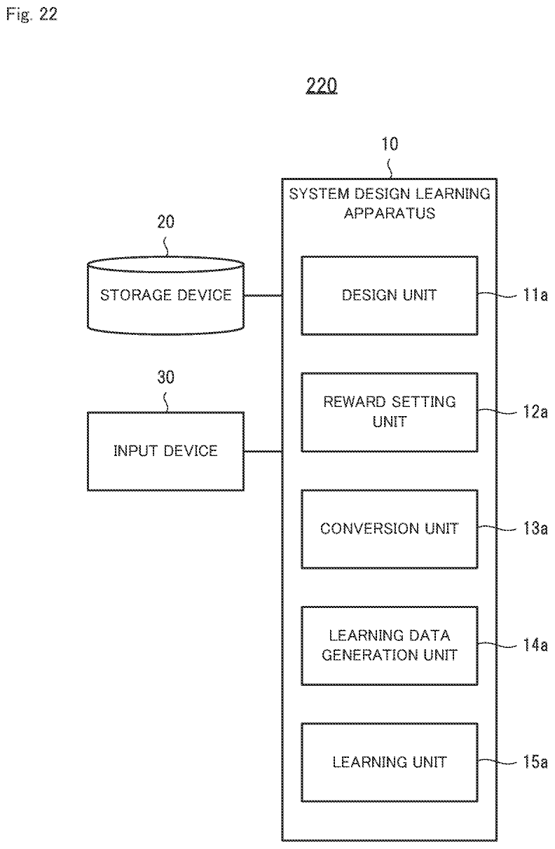

The configuration of a system design learning apparatus 220 in the second example embodiment will be described using FIG. 22. FIG. 22 is a diagram illustrating an example of the system design learning apparatus of the second example embodiment.

The system design learning apparatus 220 shown in FIG. 22 is an apparatus that performs learning on designing regarding non-functional requirements of an ICT system.

The non-functional requirements are requirements that define availability, performance, expandability, operability and maintainability, and security, for example. Specifically, the non-functional requirements are defined as a constraint formula that the system configuration (aforementioned system requirement, or system configuration idea, or concrete system configuration) has, or a constraint formula that a component included in the system configuration has.

For example, assume that the face authentication system in FIG. 1 has a function that a face authentication function communicates with a camera function and acquires video data, and the speed of the aforementioned communication needs to be 10 [Mbps] (mega-bits per second: the same applies below). In this case, the edge E1 in the system requirement R1 that represents the configuration of the face authentication system in FIG. 1 has a constraint formula that the communication speed be 10 [Mbps] or more. The constraint formula can be represented by a formula such as communication speed>=10 [Mbps], for example.

Also, if the total cost of the face authentication system needs to be ¥10 M or less, the face authentication system has a constraint formula that indicates that the cost is ¥10 M or less. The constraint formula can be represented by a formula such as cost<=¥10 M, for example.

### [Apparatus Configuration]

The system design learning apparatus 220 shown in FIG. 22 includes a design unit 11a, a reward setting unit 12a, a conversion unit 13a, a learning data generation unit 14a, and a learning unit 15a.

The design unit 11a executes concretization processing for converting abstract parts to concrete parts with respect to a system requirement, which is information representing the configuration of a system including abstract parts, generates a concrete system configuration, which is information representing the configuration of a system that does not include abstract parts, and generates configuration path information that represents the process of generating the concrete system configuration from the system requirement.

The reward setting unit 12a sets rewards for learning a system design method based on non-functional requirements. Specifically, the reward setting unit 12a sets reward for each of the system requirement, the system configuration ideas generated in a process of the concretization processing, and the concrete system configuration, which are included in the configuration path information, based on performance information that represents performance of each of the system requirement, system configuration ideas and concrete system configurations.

The conversion unit 13a generates abstract configuration path information by abstractizing the configuration path information. Specifically, the conversion unit 13a converts type information representing the types of components included in the system requirement, system configuration ideas, and concrete system configuration that are included in the configuration path information to abstraction types representing abstract types based on type definition information for converting types to abstract types, and with this generates abstract configuration path information.

The learning data generation unit 14a generates learning data by associating a reward with each of abstractized system requirement, abstractized system configuration ideas, and an abstractized concrete system configuration that are included in the abstract configuration path information. The learning unit 15a learns a system design method based on the non-functional requirements, based on the learning data.

As described above, in the second example embodiment, the time needed to perform reinforcement learning regarding large-scale system designing can be reduced.

### [Apparatus Operations]

The operations of the system design learning apparatus in the second example embodiment will be described. In the following description, the drawings are referred to as appropriate. Furthermore, in the second example embodiment, a system design learning method is implemented by causing the system design learning apparatus to operate. Accordingly, the following description of the operations of the system design learning apparatus replaces the description of the system design learning method in the second example embodiment.
Operations of the system design learning apparatus will be described.

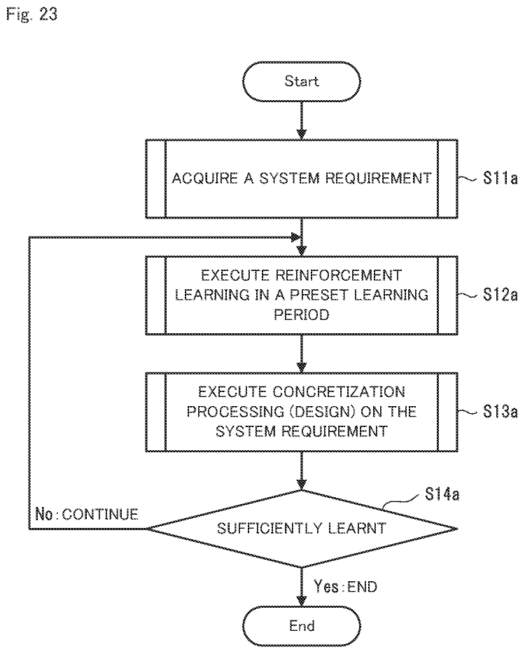

FIG. 23 is a diagram for describing an example of operations of the system design learning apparatus of the second example embodiment. First, the system design learning apparatus 220 acquires a system requirement for which learning is performed from the storage device 20 (step S11a).

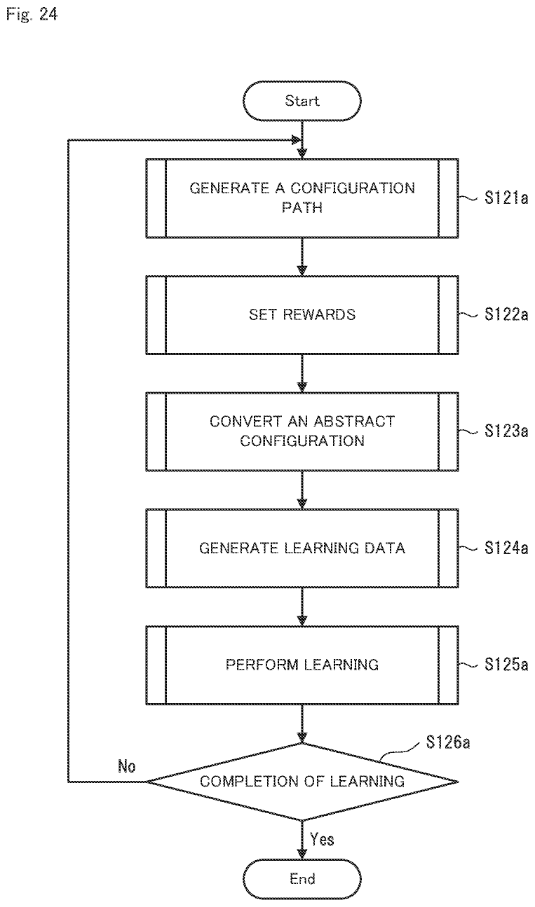

Next, the system design learning apparatus 220 executes reinforcement learning in a preset learning period using the system requirement regarding which learning is performed (step S12a). The learning period is set according to a method similar to the method described in the first example embodiment. The details of step S12a will be described later with reference to FIG. 24.

Next, the system design learning apparatus 220 estimates performance with respect to at least one concrete system configuration generated based on the system requirement using a current learning model of non-functional requirements (step S13a). A neural network is used as the learning model of non-functional requirements, for example.

Next, if it is determined that the non-function requirements have been sufficiently learnt (step S14a: Yes) based on the estimation result in step S13a, the system design learning apparatus 220 ends the processing in step S12a. Also, if it is determined that non-function requirements have not been sufficiently learnt (step S14a: No), the system design learning apparatus 220 repeats (continues) the processing in steps S12a and S13a until it is determined that the learning regarding the non-functional requirements is sufficient.

Regarding the determination as to whether or not the non-function requirements were sufficiently learnt in step S14a, the average of errors of the performance estimation results is calculated, and it is determined that learning is sufficient if the calculated average is a preset threshold C or less, for example. Alternatively, it is determined that it is sufficient if the likelihood or log likelihood of the performance estimation results is a preset threshold D or less.

The performance estimation result is, when performance of a component in a certain concrete configuration is estimated, an attribute value that represents the performance value of the component and is included in a graph that is output as a result of inputting a graph representing the configuration to a learning model of the non-functional requirement. The determination in step S14a is performed based on the error between the attribute value and the performance value obtained by actually measuring the performance of the component. The method of determining the thresholds C and D need only be a method with which it can be determined that the accuracy of performance estimation becomes sufficiently high. For example, the threshold C may be 10 [%], and the threshold D may be 0.001.
The non-functional requirement learning (step S12a) will be described.

FIG. 24 is a diagram for describing an example of operations of the non-functional requirement learning. In the non-functional requirement learning, a design method regarding non-functional requirements of an ICT system is learned.

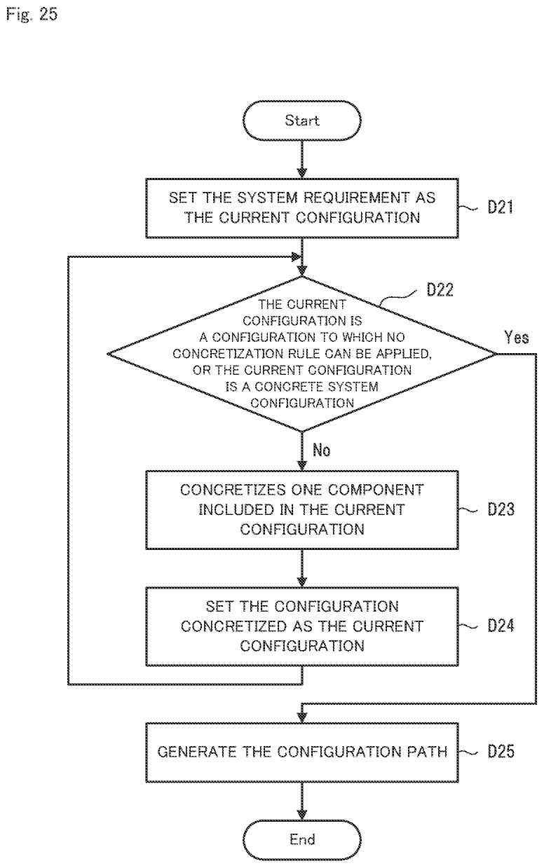

First, the design unit 11a generates a configuration path using a system requirement (step S121a). The details of step S121a will be described later with reference to FIG. 25.

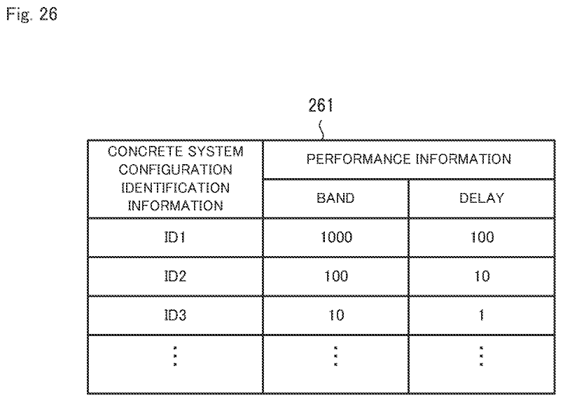

Next, the reward setting unit 12a sets a reward for each of the system configurations (aforementioned system requirement, system configuration ideas, or concrete system configurations) of the configuration path generated in step S121a (step S122a). The details of step S122a will be described later with reference to FIG. 26.

Next, the conversion unit 13a converts each of the system configurations on the configuration path generated in step S121a to an abstract configuration by executing abstraction processing thereon (step S123a). The operations in step S123a are similar to the operations in step S123 described in the first example embodiment, and therefore the description of the operations will be omitted.

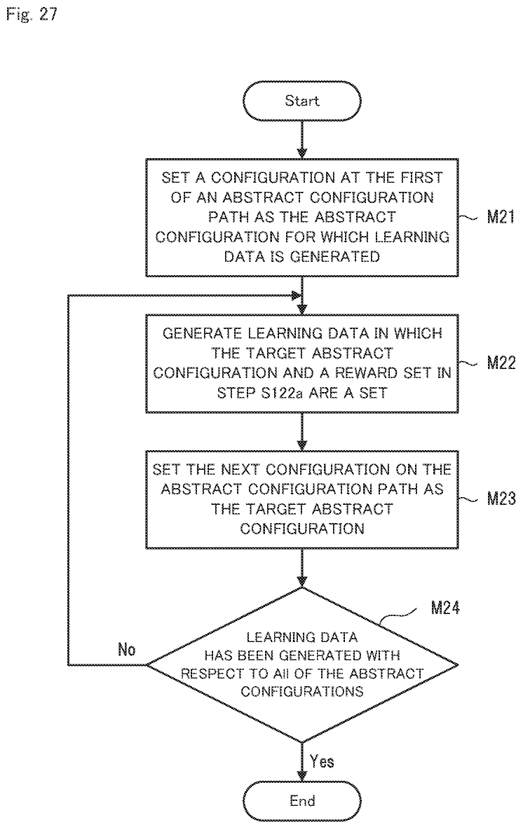

Next, the learning data generation unit 14a generates learning data by associating the abstract configuration with rewards of the configuration path, and stores the generated learning data in the storage device 20 (step S124a). The details of step S124a will be described later with reference to FIG. 27.

Next, the learning unit 15a performs learning based on the learning data (step S125a). The details of step S125a will be described later.

In this way, steps S121a to S125a are repeated in the preset learning period (step S126a).
The operations for generating the configuration path (step S121a) will be described.

FIG. 25 is a diagram for describing an example of the operations for generating the configuration path.

First, the design unit 11a sets the system requirement as the current configuration (system configuration) (step D21). Next, when there is a concretization rule that can be applied to the current configuration or the current configuration is not a concrete system configuration (step D22: No), the design unit 11a shifts the processing to step D23. Also, when there is no concretization rule that can be applied to the current configuration or the current configuration is a concrete system configuration (step D22: Yes), the design unit 11a shifts the processing to step D25.

Next, the design unit 11a concretizes one component included in the current configuration by executing concretization processing (step D23). Next, the design unit 11a sets the configuration (system configuration idea) concretized in step D23 to the current configuration (step D24).

Next, the design unit 11a generates, from the system configuration (system requirement, system configuration ideas, concrete system configuration) that appeared in the processing in steps D23 and D24 described above, a path (configuration path information in which the configuration is stored in chronological order (configuration path)) from the system requirement to the generation of the current concrete system configuration (step D25).
Operations of the reward setting (step S122a) will be described.

In step S122a, the reward setting unit 12a acquires performance data corresponding to a final configuration of the configuration path (concrete system configuration) by referring to the performance information stored in the storage device 20, and determines a reward based on the value indicated by the acquired performance data.

FIG. 26 is a diagram for describing an example of the data structure of the performance information. In the performance information, concrete system configuration identification information representing a concrete system configuration of which performance has been measured in the past is associated with performance data representing a performance value for each type of non-functional requirement. In the example in FIG. 26, “ID1”, “ID2”, “ID3”, . . . are stored in “concrete system configuration identification information”. Also, in the “performance information” in FIG. 26, “1000”, “100”, “10”, . . . are stored in “band”, and “100”, “10”, “1”, . . . are stored in “delay”. Note that the performance data is not limited to the aforementioned communication band and delay, and may also be performance data other than the band and delay.

For example, iPerf (registered trademark), which is a tool for measuring network performance and executing tuning, or the like is used to measure the band. Also, software such as ping, which is implemented in an ordinary OS in advance, is used to measure the delay. Note that these methods are merely examples, and there is no limitation thereto. Also, an appropriate measuring method is adopted according to the type of performance to be measured.

Regarding the reward, the value of the performance value itself is simply set as the value of the reward. For example, when the band is 100 [Mbps], the reward is 100. Note that which unit is to be used for each performance value is determined in advance, as appropriate (e.g., based on the frequency of use). For example, when Mbps is determined to be used as the unit of the band, 1 [Gbps] (giga-bits per second: the same applies below) is 1000 [Mbps], and therefore the reward is 1000. Also, it is convenient that the value to be learned is a small-scale value, and therefore the value of the reward may be a value obtained by performing logarithmic conversion on a performance value.

The reward may be provided for each type of non-functional requirement such as a band and a delay, or may be united into one integrated reward, for example.

When the reward is provided for each type of non-functional requirement, the reward may be the value of performance data (reward determination method 1). Also, for performance that improves as the value increases, the reward regarding the corresponding non-functional requirement may be the value of the performance data as is, and for performance that decreases as the value decreases, the reward regarding the corresponding non-functional requirement may be an inverse of the value of the performance (reward determination method 2).

Also, when the reward is united into one integrated reward, it is preferable that the reward is obtained by applying appropriate weights to the rewards of the respective types of the non-functional requirements determined by the reward determination method 2 and adding the weighted rewards.
Operations for generating learning data (step S124a) will be described in more detail.

FIG. 27 is a diagram for describing an example of the operations for deciding rewards and generating learning data.

First, the learning data generation unit 14a sets a configuration (system configuration) at the head (first) of an abstract configuration path as the abstract configuration for which learning data is generated (step M21). The learning data generation unit 14a generates learning data in which the target abstract configuration and a reward set in step S122a are a set, and stores the generated learning data in the storage device 20 (step M22).

Next, the learning data generation unit 14a sets the next configuration on the abstract configuration path as the abstract configuration for which learning data is to be generated (step M23).

Next, if learning data is not generated with respect to all of the configurations on the abstract configuration path (if learning data is not generated up to the configuration at the tail (last) of the abstract configuration path) (step M24: No), the learning data generation unit 14a repeats the processing in steps M22 and M23. Also, if learning data is generated with respect to all of the configurations on the abstract configuration path (if learning data is generated up to the configuration at the tail (last) of the abstract configuration path) (step M24: Yes), the learning data generation unit 14a ends the processing for generating the learning data.
·Operations for learning (step S125a) will be described in more detail.

Operations in step S125a will be described. The learning model is a GNN (Graph Neural Network) to which graph information in which the nodes and edges in the graph and the graph itself has an attribute value are input and that outputs graph information in a similar format.

The operations in step S125a are similar to the operations in step S125 described in the first example embodiment, and therefore the detailed description of the operations will be omitted. Note that the point that differs from the first example embodiment is how learning is performed (step L16), and therefore two examples (1) and (2) will be described regarding step L16 of the first example embodiment shown in FIG. 21.

The example (1) is to learn expected values of rewards regarding non-functional requirements. In this case, machine learning is performed so that, when a configuration included in learning data is input to a learning model, an output error of the learning model is corrected such that the evaluation value that is output with respect to an abstract configuration included in the learning data approaches the value of a reward included in the learning data. Specifically, a loss function is set to calculate a mean square error between an attribute value and the corresponding reward, with respect to sets included in VPS1, and the learning model is trained so as to minimize the loss function.

The example (2) is to learn a probability density function of rewards regarding non-functional requirements. In this case, learning is performed so as to correct the parameters of a probability density function such that, when a configuration included in learning data is input to a learning model, the likelihood of the probability density function based on the parameters of a probability density function included in the learning data increases with respect to the values of rewards included in the learning data.

When the probability density function of rewards is assumed to follow a mixed Gaussian distribution, for example, the parameters of the probability density function are an average value μ, a variance Σ, and a mixing coefficient π in each of the Gaussian distributions that constitute the mixed Gaussian distribution. This assumption is a typical example, and there is no limitation thereto. Also, it is preferable that an EM algorithm is to be applied, for example, as the method of correcting the parameters of a probability density function so as to increase the likelihood of the probability density function described above, but there is no limitation thereto.

### Effects of Second Example Embodiment

According to the second example embodiment, with respect to a large-scale system as well, learning on designing regarding non-functional requirements can be performed.

Also, the types of components included in a configuration (system configuration) are abstractized, learning data including an abstract configuration is generated, and learning is performed using the learning data, and as a result, rough evaluation in which an influence due to the difference between components is excluded can be performed. As a result, the time needed to individually learn configurations in which only the components included therein are different can be reduced, and with respect to a large-scale system as well, learning about design regarding functional requirements can be performed.

### [Program]

The program according to the second example embodiment may be a program that causes a computer to execute steps S11a to S14a shown in FIG. 23. By installing this program in a computer and executing the program, the system design learning apparatus and the system design learning method according to the second example embodiment can be realized. Further, the processor of the computer performs processing to function as the design unit 11a, the reward setting unit 12a, the conversion unit 13a, the learning data generation unit 14a and the learning unit 15a.

Also, the program according to the second example embodiment may be executed by a computer system constructed by a plurality of computers. In this case, for example, each computer may function as any of the design unit 11a, the reward setting unit 12a, the conversion unit 13a, the learning data generation unit 14a and the learning unit 15a.

### Third Example Embodiment

Hereinafter, a third example embodiment will be described with reference to the drawings. Note that, in the drawings described below, the elements that have the same or corresponding functions are given the same reference numerals and description thereof may not be repeated.

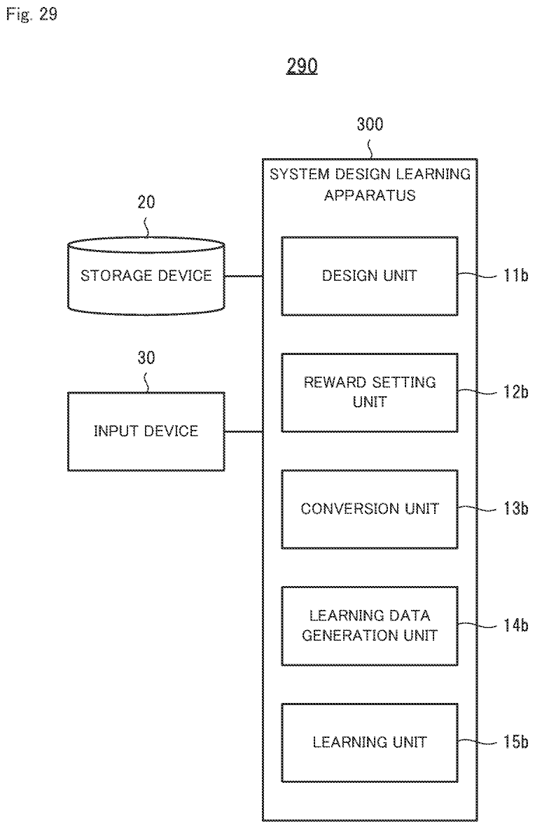

The configuration of a system design learning apparatus 300 in the third example embodiment will be described using FIG. 29. FIG. 29 is a diagram illustrating an example of the system design learning apparatus of the third example embodiment.

The system design learning apparatus 300 shown in FIG. 29 is an apparatus that performs learning on designing regarding non-functional requirements of an ICT system.

The non-functional requirements are requirements that defines availability, performance, expandability, operability and maintainability, and security, for example. Specifically, the non-functional requirements are defined as a constraint formula that the system configuration (aforementioned system requirement, or system configuration idea, or concrete system configuration) has, or a constraint formula that a component included in the system configuration has.

For example, assume that the face authentication system in FIG. 1 has a function that a face authentication function communicates with a camera function and acquires video data, and the speed of the aforementioned communication needs to be 10 [Mbps] (mega-bits per second: the same applies below) or more. In this case, the edge E1 in the system requirement R1 that represent the configuration of the face authentication system in FIG. 1 has a constraint formula that the communication speed is 10 [Mbps] or more. The constraint formula can be represented by a formula such as communication speed>=10 [Mbps], for example.

Also, if the total cost of the face authentication system needs to be ¥10 M or less, the face authentication system has a constraint formula that represents that the cost is ¥10 M or less. The constraint formula can be represented by a formula such as cost<=¥10 M, for example.

### [Apparatus Configuration]

The system design learning apparatus 300 shown in FIG. 29 includes a design unit 11b, a reward setting unit 12b, a conversion unit 13b, a learning data generation unit 14b, and a learning unit 15b.

The design unit 11b executes concretization processing for converting abstract parts to concrete parts with respect to a system requirement, which is information representing the configuration of a system including abstract parts, generates a concrete system configuration, which is information representing the configuration of a system that does not include abstract parts, and generates configuration path information that represents the process of generating the concrete system configuration from the system requirement.

The reward setting unit 12b sets rewards for learning a system design method based on non-functional requirements. Specifically, the reward setting unit 12b sets reward for each of the system requirement, the system configuration ideas generated in a process of the concretization processing, and the concrete system configuration, which are included in the configuration path information, based on performance information that represents performance of each of the system requirement, system configuration ideas and concrete system configurations.

The conversion unit 13b generates abstract configuration path information by abstractizing the configuration path information. Specifically, the conversion unit 13b generates abstract configuration path information by converting the type information of a component, out of pieces of type information that represent types of components that are included in the system requirement, system configuration ideas, and concrete system configurations that are included in the configuration path information, that exerts a small influence on the index of a non-functional requirement to be learned to an abstraction type that represents an abstract type based on type definition information for converting a type to an abstract type.

In other words, the conversion unit 13b determines whether each of the types of components included in the system requirement, system configuration ideas, and concrete system configurations is a type that largely influences the index of a non-functional requirement under learning, using non-functional requirement influencing type information in which non-functional requirement type information representing the types of the non-functional requirements is associated with a set of type information representing types that largely influences the indices of the non-functional requirements, and if it is determined that the type does not exert a large influence, abstractizes the type.

The learning data generation unit 14b generates learning data by associating a reward with each of an abstractized system requirement, abstractized system configuration ideas, and an abstractized concrete system configuration that are included in the abstract configuration path information. The learning unit 15b learns a system design method based on the non-functional requirements, based on the learning data.

As described above, in the third example embodiment, the time needed to perform reinforcement learning regarding large-scale system designing can be reduced.

### [Apparatus Operations]

The operations of the system design learning apparatus in the third example embodiment will be described. In the following description, the drawings are referred to as appropriate. Furthermore, in the third example embodiment, a system design learning method is implemented by causing the system design learning apparatus to operate. Accordingly, the following description of the operations of the system design learning apparatus replaces the description of the system design learning method in the third example embodiment.
Operations of the system design learning apparatus will be described.

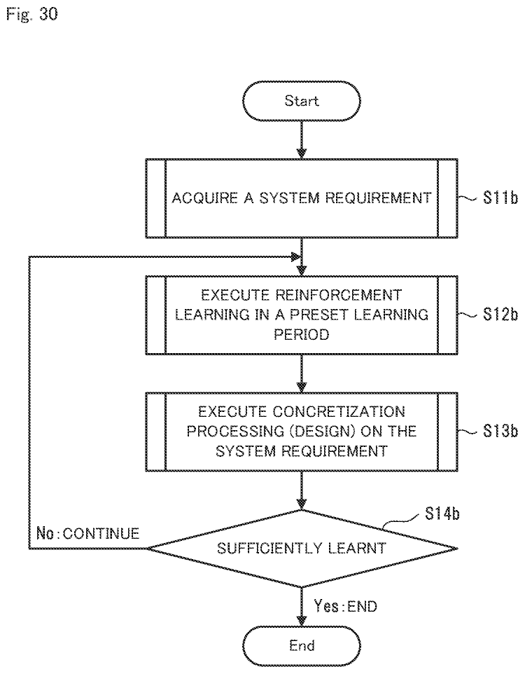

FIG. 30 is a diagram for describing an example of operations of the system design learning apparatus of the third example embodiment. First, the system design learning apparatus 300 acquires a learning-target system requirement from the storage device 20 (step S11b).

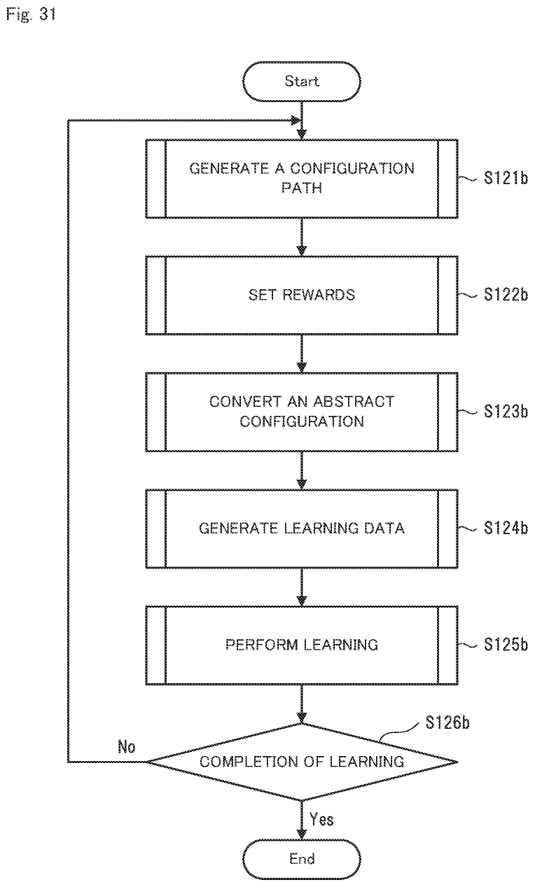

Next, the system design learning apparatus 300 executes reinforcement learning in a preset learning period using the learning-target system requirement (step S12b). The learning period is set with a method similar to the method described in the first example embodiment. The details of step S12b will be described later with reference to FIG. 31.

Next, the system design learning apparatus 300 performs performance estimation with respect to at least one concrete system configuration that is generated based on the system requirement using a current learning model of non-functional requirements (step S13b). A neural network is used as the learning model of non-functional requirements, for example.

Next, if it is determined that the non-functional requirements have been sufficiently learnt (step S14b: Yes) based on the estimation result in step S13b, the system design learning apparatus 300 ends the processing in step S12b. Also, if it is determined that the non-functional requirements have not been sufficiently learnt (step S14b: No), the system design learning apparatus 300 repeats (continues) the processing in steps S12b and S13b until it is determined that the non-functional requirements have been sufficiently learnt.

Regarding the determination whether or not the non-functional requirements have been sufficiently learnt in step S14b, an average of errors of the performance estimation results is calculated, and it is determined that it is sufficient if the calculated average is a preset threshold C or less, for example. Alternatively, it is determined that it is sufficient if the likelihood or log likelihood of the performance estimation results is a preset threshold D or less.

The performance estimation result is, when performance of a component in a certain concrete configuration is estimated, an attribute value that represents the performance value of the component and is included in a graph that is output as a result of inputting a graph representing the configuration to a learning model of the non-functional requirement. The determination in step S14b is performed based on the error between the attribute value and the performance value obtained by actually measuring the performance of the component. The method of determining the thresholds C and D needs only be a method with which it can be determined that the accuracy of performance estimation becomes sufficiently high. For example, the threshold C may be 10 [%], and the threshold D may be 0.001.
The non-functional requirement learning (step S12b) will be described.

FIG. 31 is a diagram for describing an example of the operations of the non-functional requirement learning. In the non-functional requirement learning, a design method regarding non-functional requirements of an ICT system is learned.

First, the design unit 11b generates a configuration path using a system requirement (step S121b). The operation in step S121b is similar to the operation in step S121a described in the second example embodiment, and therefore the description of the operation will be omitted.

Next, the reward setting unit 12b sets reward to each of the system configurations (aforementioned system requirement, system configuration ideas, or concrete system configurations) of the configuration path generated in step S121b (step S122b). The operation in step S122b is similar to the operation in step S122a described in the second example embodiment, and therefore the description of the operation will be omitted.

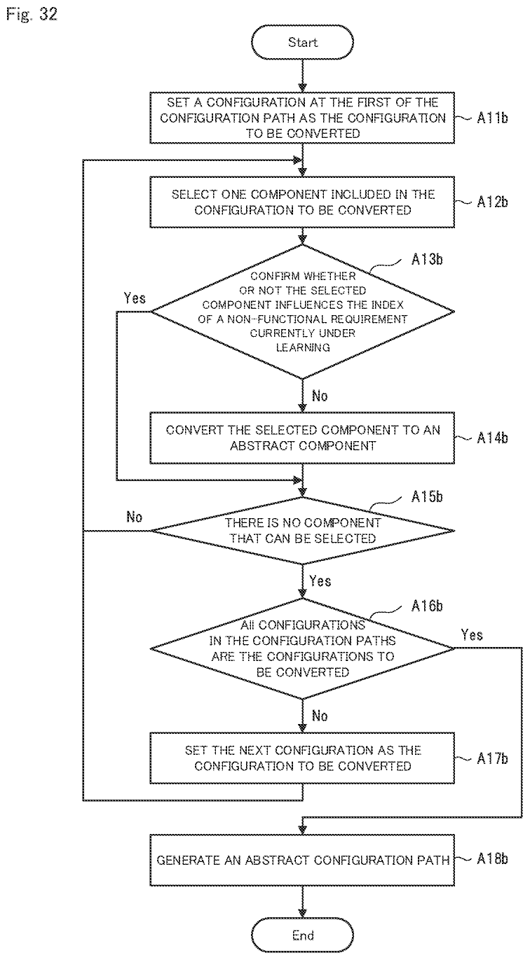

Next, the conversion unit 13b converts each of the system configurations of the configuration path generated in step S121b to an abstract configuration by executing abstraction processing thereon (step S123b). The details of step S123b will be described later with reference to FIG. 32.

Next, the learning data generation unit 14b generates learning data by associating the abstract configurations with rewards of the configuration path, and stores the generated learning data in the storage device 20 (step S124b). The operation in step S124b is similar to the operation in step S124a described in the second example embodiment, and therefore the description of the operation will be omitted.

Next, the learning unit 15b performs learning based on the learning data (step S125b). The operation in step S125b is similar to the operation in step S125a described in the second example embodiment, and therefore the description of the operation will be omitted.

In this way, steps S121b to S125b are repeated in the preset learning period (step S126b).
Operations for abstractizing the configuration path (step S123b) will be described more in details.

FIG. 32 is a diagram for describing an example of operations for generating the abstract configuration path.

First, the conversion unit 13b sets a configuration (system configuration) at the head (first) of the configuration path as the configuration (system configuration) to be converted (step A11b). Next, the conversion unit 13b selects one component from all of the components included in the configuration to be converted (step A12b).

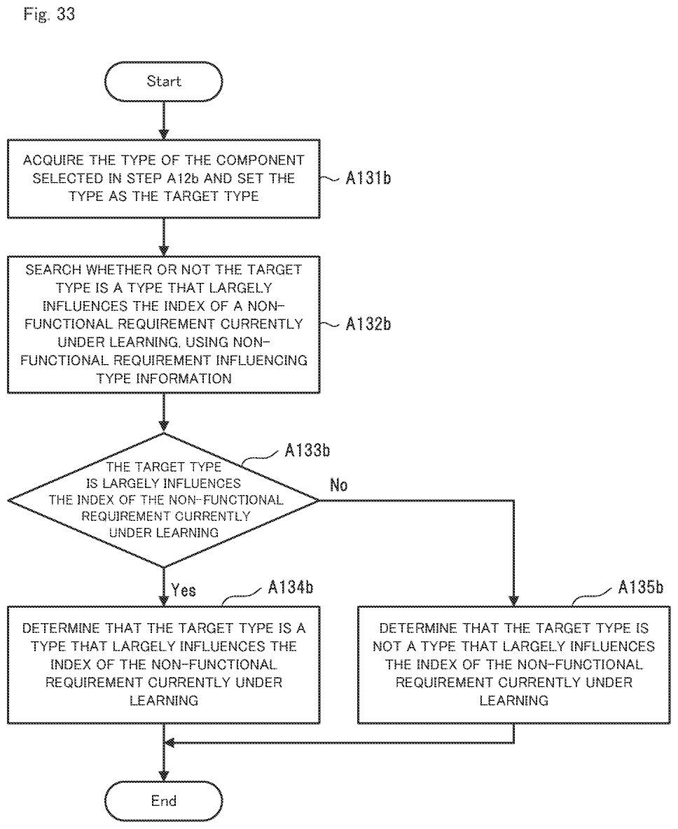

Next, the conversion unit 13b confirms whether or not the selected component influences the index of a non-functional requirement currently under learning (step A13b). If the selected component is not a component that largely influences the index of the non-functional requirement currently under learning (step A13b: No), the conversion unit 13b converts the selected component to an abstract component (step A14b). If the selected component is a component that largely influences the index of the non-functional requirement currently under learning (step A13b: Yes), the processing is shifted to step A15b. The details of step A13b will be described later with reference to FIG. 33. The operation in step A14b is similar to the operation in step A13 described in the first example embodiment, and therefore the description of the operation will be omitted.

Next, if there is no component that can be selected (step A15b: Yes), the conversion unit 13b shifts the processing to step A16b. Also, if there is a component that can be selected (step A15b: No), the conversion unit 13b shifts the processing to step A12b, and repeats the processing in steps A12b to A14b until no unselected component remains.

Next, if all of the configurations (system configurations) in the configuration paths have not been set to a configuration to be converted (if the configuration to be converted has not reached the configuration (system configuration) at the tail (last) of the configuration path) (step A16b: No), the conversion unit 13b sets the next configuration (system configuration) in the configuration path as the configuration to be converted (step A17b). Next, the conversion unit 13b shifts the processing to step A12b.

Also, if all of the configurations in the configuration paths have been set to a configuration to be converted (if the configuration to be converted has reached the configuration (system configuration) at the tail (last) of the configuration path) (step A16b: Yes), the conversion unit 13b executes the processing in step A18b. That is, the conversion unit 13b stores all of the abstract configurations generated in the aforementioned conversion processing in steps A11b to A17b (abstractized system configurations) and all configurations that are not converted in chronological order, and with this generates an abstract configuration path (step A18b).

The abstract configuration path ACP1 shown in FIG. 17 is obtained by abstractizing the configuration path CP1 shown in FIG. 13. Note that the abstractized system requirement “AR1”, system configuration idea “AR2”, and concrete system configuration “AR5” in the abstract configuration path ACP1 are shown in the order of the system requirement “R1”, system configuration idea “R2”, and concrete system configuration “R5” shown in FIGS. 11 and 12.
Operations of confirming whether or not a component influences the index of a non-functional requirement under learning (step A13b) will be described in more details.

FIG. 33 is a diagram for describing an example of operations for generating abstract configurations.

First, the conversion unit 13b acquires the type of the component selected in step A12b and sets the type as the target type (step A131b). Specifically, the conversion unit 13b acquires the type corresponding to the selected component from component information. For example, function information corresponding to the selected component is acquired by referring to the component information. Alternatively, type information representing the type may also be associated with the component identification information and stored in the component information, and the type information corresponding to the selected component may be acquired.

Next, the conversion unit 13b searches whether or not the target type is a type that largely influences the index of a non-functional requirement currently under learning, using non-functional requirement influencing type information created in advance (step A132b). The non-functional requirement influencing type information is information in which non-functional requirement type information that represents the type of a non-functional requirement is associated with a set of pieces of type information that represent types that exert a large influence on the index of the non-functional requirement. The non-functional requirement influencing type information is stored in the storage device 20 or the like.

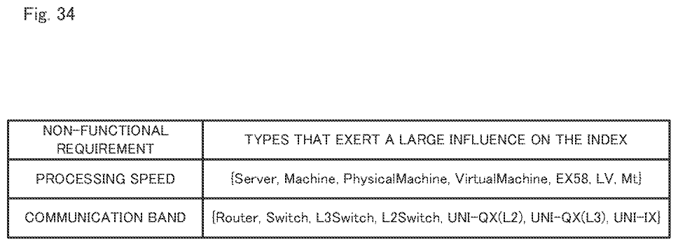

FIG. 34 is a diagram for describing an example of the data structure of non-functional requirement influencing type information. In the example in FIG. 34, as the “non-functional requirement” that represents types of non-functional requirements included in the non-functional requirement influencing type information, the types (names), namely “processing speed” and “communication band”, are stored. Also, in the example in FIG. 34, as the set of pieces of type information that represent types that exert a large influence on the index of the non-functional requirement, “Server”, “Machine”, “PhysicalMachine”, “VirtualMachine”, “EX58”, “LV”, and “Mt” are associated with the “processing speed”, and “Router”, “Switch”, “L3Switch”, “L2Switch”, “UNI-QX (L2)”, “UNI-QX (L3)”, and “UNI-IX” are associated with the “communication band”.

The “Server” is abstract type information that represents overall servers. The “Machine” is abstract type information that represents overall client PCs. The “PhysicalMachine” is abstract type information that represents overall physical client PCs. The “VirtualMachine” is abstract type information that represents virtual client PCs. The “EX58” is concrete type information that represents a server having a product name EX58. The “LV” is concrete type information that represents a physical client PC having a product name LV. The “Mt” is concrete type information that represents a physical client PC having a product name Mt.

The “Router” is abstract type information that represents overall routers. The “Switch” is abstract type information that represents overall network switches. The “L3Switch” is abstract type information that represents overall L3 switches. The “L2Switch” is abstract type information that represents overall L2 switches. The “UNI-QX (L2)” is concrete type information that represents an L2 switch having a product name UNI-QX (L2). The “UNI-QX (L3)” is concrete type information that represents an L3 switch having a product name UNI-QX (L3). The “UNI-IX” is concrete type information that represents a router having a product name UNI-IX.

Note that the non-functional requirement influencing type information is not limited to the example in FIG. 34, and the type of a non-functional requirement other than the “processing speed” and “communication band” may be associated with a set of pieces of type information representing types that exert a large influence on the index of the non-functional requirement and stored, and also a set of pieces of type information different form the aforementioned example may be associated with the “processing speed” and “communication band” and stored.

Next, as a result of the search in step A132b, if the target type is included in the set of types associated with types of the non-functional requirements currently under learning that are included in the non-functional requirement influencing type information (step A133b: Yes), the conversion unit 13b determines that the target type is a type that largely influences the index of the non-functional requirement currently under learning, and ends step A13b (step A134b). On the other hand, if the target type is not included in the set of types associated with types of the non-functional requirements currently under learning that are included in the non-functional requirement influencing type information (step A133b: No), the conversion unit 13b determines that the target type is not a type that largely influences the index of the non-functional requirement currently under learning, and ends step A13b (step A135b).

### Effects of Third Example Embodiment

According to the third example embodiment, with respect to a large-scale system as well, learning on designing regarding non-functional requirements can be performed, while taking the difference of components that exert a large influence on the index of a non-functional requirement into consideration.

As a result of abstractizing the types of components that exert a small influence on the indices of non-functional requirements, out of the types of the components included in the configuration (system configuration), generating learning data including abstract configurations, and performing learning using the learning data, learning can be performed regarding evaluation due to differences of components that exert a large influence on the index of a non-functional requirement, and at the same time, the time needed to separately perform learning on the difference of configuration caused by the difference of components that exert a small influence on the index of a non-functional requirement can be reduced. As a result, with respect to a large-scale system as well, learning on designing regarding non-functional requirements can be accurately performed.

### [Program]

The program according to the third example embodiment may be a program that causes a computer to execute steps S11b to S14b shown in FIG. 30. By installing this program in a computer and executing the program, the system design learning apparatus and the system design learning method according to the third example embodiment can be realized. Further, the processor of the computer performs processing to function as the design unit 11b, the reward setting unit 12b, the conversion unit 13b, the learning data generation unit 14b and the learning unit 15b.

Also, the program according to the third example embodiment may be executed by a computer system constructed by a plurality of computers. In this case, for example, each computer may function as any of the design unit 11b, the reward setting unit 12b, the conversion unit 13b, the learning data generation unit 14b and the learning unit 15b.

### [Physical Configuration]

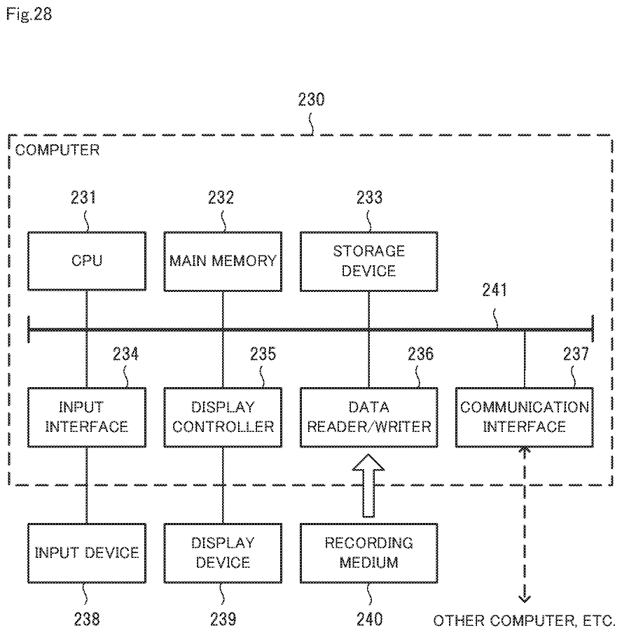

Here, a computer that realizes the system design learning apparatus by executing the program according to the example embodiments will be described with reference to FIG. 28. FIG. 28 is a diagram for describing an example of a computer that realizes the system design learning apparatus of the first to third example embodiments.

As shown in FIG. 28, a computer 230 includes a CPU (Central Processing Unit) 231, a main memory 232, a storage device 233, an input interface 234, a display controller 235, a data reader/writer 236, and a communications interface 237. These units are each connected so as to be capable of performing data communications with each other through a bus 241. Note that the computer 230 may include a GPU (Graphics Processing Unit) or an FPGA (Field-Programmable Gate Array) in addition to the CPU 231 or in place of the CPU 231.

The CPU 231 opens the program (code) according to this example embodiment, which has been stored in the storage device 233, in the main memory 232 and performs various operations by executing the program in a predetermined order. The main memory 232 is typically a volatile storage device such as a DRAM (Dynamic Random Access Memory). Also, the program according to this example embodiment is provided in a state being stored in a computer-readable recording medium 240. Note that the program according to this example embodiment may be distributed on the Internet, which is connected through the communications interface 237. Note that the computer-readable recording medium 240 is a non-volatile recording medium.

Also, other than a hard disk drive, a semiconductor storage device such as a flash memory can be given as a specific example of the storage device 233. The input interface 234 mediates data transmission between the CPU 231 and an input device 238, which may be a keyboard or mouse. The display controller 235 is connected to a display device 239, and controls display on the display device 239.

The data reader/writer 236 mediates data transmission between the CPU 231 and the recording medium 240, and executes reading of a program from the recording medium 240 and writing of processing results in the computer 230 to the recording medium 240. The communications interface 237 mediates data transmission between the CPU 231 and other computers.

Also, general-purpose semiconductor storage devices such as CF (Compact Flash (registered trademark)) and SD (Secure Digital), a magnetic recording medium such as a Flexible Disk, or an optical recording medium such as a CD-ROM (Compact Disk Read-Only Memory) can be given as specific examples of the recording medium 240.

Also, instead of a computer in which a program is installed, the system design learning apparatus according to the first to third example embodiments can also be realized by using hardware corresponding to each unit. Furthermore, a portion of the system design learning apparatus may be realized by a program, and the remaining portion realized by hardware.

Although the present invention of this application has been described with reference to the first to third exemplary embodiments, the present invention of this application is not limited to the above the first to third exemplary embodiments. Within the scope of the present invention of this application, various changes that can be understood by those skilled in the art can be made to the configuration and details of the present invention of this application.

As described above, according to the present disclosure, the time needed to perform reinforcement learning for designing a large-scale system can be reduced. It is useful in a field where automatic design of an ICT system is required.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A system design learning apparatus comprising:
a design unit that, with respect to a system requirement that is information representing a configuration of a system including an abstract part, executes concretization processing in which the abstract part is converted to a concrete part, generates a concrete system configuration that is information representing a configuration of the system that does not include an abstract part, and generates configuration path information representing a process of generating the concrete system configuration from the system requirement;
a reward setting unit that sets rewards to the system requirement, a system configuration idea generated in a process of the concretization processing, and the concrete system configuration that are included in the configuration path information, respectively;
a conversion unit that generates abstract configuration path information by abstractizing the configuration path information;
a learning data generation unit that generates learning data by associating the rewards with an abstractized system requirement, an abstractized system configuration idea, and an abstractized concrete system configuration that are included in the abstract configuration path information, respectively; and
a learning unit that learns a design method of the system based on the learning data.

2. The system design learning apparatus according to claim 1, wherein the conversion unit generates the abstract configuration path information by converting pieces of type information that respectively represent types of components included in the system requirement, the system configuration idea, and the concrete system configuration that are included in the configuration path information to abstraction types that represent abstract types based on type definition information for converting the types to abstract types.

3. The system design learning apparatus according to claim 2, wherein the conversion unit determines whether each of the types of components included in the system requirement, the system configuration idea, and the concrete system configuration is a type that largely influences an index of a non-functional requirement under learning using non-functional requirement influencing type information that is information in which non-functional requirement type information representing the type of a non-functional requirement is associated with a set of pieces of type information representing types that largely influence an index of the non-functional requirement, and if it is determined that the type does not exert a large influence, abstractizes the type.

4. The system design learning apparatus according to claim 2,
wherein the learning unit learns a design method of the system based on a functional requirement, and
the reward setting unit sets rewards for learning the design method of the system based on the functional requirement.

5. The system design learning apparatus according to claim 2,
wherein the learning unit learns a design method of the system based on a non-functional requirement, and
the reward setting unit sets rewards for learning the design method of the system based on the non-functional requirement.

6. The system design learning apparatus according to claim 5, wherein the reward setting unit generates rewards for learning a design method regarding the non-functional requirement of the system based on pieces of performance information that respectively represent performances of the system requirement, the system configuration idea, and the concrete system configuration that are included in the configuration path information.

7. A system design learning method for an information processing apparatus to carry out:
with respect to a system requirement that is information representing a configuration of a system including an abstract part, executing concretization processing in which the abstract part is converted to a concrete part, generating a concrete system configuration that is information representing a configuration of the system that does not include an abstract part, and generating configuration path information representing a process of generating the concrete system configuration from the system requirement;
setting rewards to the system requirement, a system configuration idea generated in a process of the concretization processing, and the concrete system configuration that are included in the configuration path information, respectively;
generating abstract configuration path information by abstractizing the configuration path information;
generating learning data by associating the rewards with an abstractized system requirement, an abstractized system configuration idea, and an abstractized concrete system configuration that are included in the abstract configuration path information, respectively; and
learning a design method of the system based on the learning data.

8. A non-transitory computer-readable recording medium including a program recorded on the computer-readable recording medium, the program including instructions that cause the computer to carry out:
with respect to a system requirement that is information representing a configuration of a system including an abstract part, executing concretization processing in which the abstract part is converted to a concrete part, generating a concrete system configuration that is information representing a configuration of the system that does not include an abstract part, and generating configuration path information representing a process of generating the concrete system configuration from the system requirement;
setting rewards to the system requirement, a system configuration idea generated in a process of the concretization processing, and the concrete system configuration that are included in the configuration path information, respectively;
generating abstract configuration path information by abstractizing the configuration path information;
generating learning data by associating the rewards with an abstractized system requirement, an abstractized system configuration idea, and an abstractized concrete system configuration that are included in the abstract configuration path information, respectively; and
learning a design method of the system based on the learning data.
